(19) United States
(12) Patent Application Publication
(10) Pub. No.: US 2018/0174940 A1
(43) Pub. Date: Jun. 21, 2018

(54) FINE-FEATURED TRACES FOR INTEGRATED CIRCUIT PACKAGE SUPPORT STRUCTURES

(71) Applicant: Intel Corporation, Santa Clara, CA (US)

(72) Inventors: Shelby Ferguson, Lacey, WA (US); Gong Ouyang, Olympia, WA (US); Russell S. Aoki, Tacoma, WA (US); Zhichao Zhang, Chandler, AZ (US); Kai Xiao, University Place, WA (US)

(73) Assignee: Intel Corporation, Santa Clara, CA (US)

(21) Appl. No.: 15/383,858

(22) Filed: Dec. 19, 2016

(51) Int. Cl. H01L 23/34; H01L 23/373; H01L 23/498

(52) U.S. Cl. CPC H01L 23/345; H01L 23/49838; H01L 23/49816; H01L 23/373

(57) ABSTRACT

Disclosed herein are fine-featured traces for integrated circuit (IC) package support structures, and related systems, devices, and methods. For example, a device may include a printed circuit board (PCB) having an insulating material and a heater trace on the insulating material. In some embodiments, the heater trace may have a section with a width less than 3.5 mils. In some embodiments, a section of the heater trace may be adjacent to a burned portion of the insulating material.

### BACKGROUND

Integrated circuit (IC) packages often include computing components (e.g., processing devices) that generate significant heat during operation. This heat is typically managed by heat sinks and other heat dissipation devices, and by restricting the performance of the computing component to stay within a temperature range of reliable operation.

### BRIEF DESCRIPTION OF THE DRAWINGS

Embodiments will be readily understood by the following detailed description in conjunction with the accompanying drawings. Embodiments are illustrated by way of example, and not by way of limitation, in the figures of the accompanying drawings.

FIG. 1 is a side cross-sectional view of an integrated circuit (IC) package assembly including an IC package disposed on an IC package support structure, in accordance with various embodiments.

FIG. 2 is a side cross-sectional view of an embodiment of the IC package assembly of FIG. 1 in which the IC package support structure is an interposer, in accordance with various embodiments.

FIG. 3 is a side cross-sectional view of an embodiment of the IC package assembly of FIG. 1 in which the IC package support structure is a printed circuit board (PCB), in accordance with various embodiments.

FIG. 4 is a side cross-sectional view of an assembly subsequent to bringing a heater control device and an IC package in proximity to the IC package support structure of FIG. 1, in accordance with various embodiments.

FIG. 5 is a side cross-sectional view of an assembly subsequent to using the heater control device of FIG. 4 to couple the IC package to the IC package support structure, in accordance with various embodiments.

FIG. 6 is a top view of a stack of heater traces disposed in multiple layers of an IC package support structure, in accordance with various embodiments.

FIG. 7 is a top view of a layer in an IC package support structure including a heater trace with a narrowed section, in accordance with various embodiments.

FIGS. 8A-8C illustrate various stages in the manufacture of the layer of FIG. 7, in accordance with various embodiments.

FIG. 9 is a top view of a layer in an IC package support structure including a heater trace with multiple narrowed sections, in accordance with various embodiments.

FIGS. 10A-10B illustrate various stages in the manufacture of the layer of FIG. 9, in accordance with various embodiments.

FIG. 11 is a top view of a layer in an IC package support structure including heater traces with multiple narrowed sections, in accordance with various embodiments.

FIGS. 12A-12B illustrate various stages in the manufacture of the layer of FIG. 11, in accordance with various embodiments.

FIG. 13 is a top view of a layer in an IC package support structure including heater traces narrower than a design rule minimum trace width, in accordance with various embodiments.

FIGS. 14A-14B illustrate various stages in the manufacture of the layer of FIG. 13, in accordance with various embodiments.

FIG. 15 is a top view of a layer in an IC package support structure including heater traces and a metal plane, in accordance with various embodiments.

FIGS. 16A-16B illustrate various stages in the manufacture of the layer of FIG. 15, in accordance with various embodiments.

FIG. 17 is a block diagram of a reflow control system, in accordance with various embodiments.

FIG. 18 is a flow diagram of a method of manufacturing an IC package support structure, in accordance with various embodiments.

FIG. 19 is a flow diagram of a method of attaching IC packages to an IC package support structure, in accordance with various embodiments.

FIG. 20 is a block diagram of an example computing device that may include an IC package support structure in accordance with the teachings of the present disclosure.

### DETAILED DESCRIPTION

Disclosed herein are fine-featured traces for integrated circuit (IC) package support structures, and related systems, devices, and methods. For example, a device may include a printed circuit board (PCB) having an insulating material and a heater trace on the insulating material. In some embodiments, the heater trace may have a section with a width less than 3.5 mils. In some embodiments, a section of the heater trace may be adjacent to a burned portion of the insulating material.

Some IC package assemblies may include an IC package support structure with heaters designed to cause local reflow of the solder attaching an IC package to the support structure (e.g., to facilitate the removal and reattachment of the IC package without the need for sockets or factory machinery). In such assemblies, thermal mismatch between materials used in the IC package assembly may result in deformation of various components in the IC package assembly as the heaters cause solder reflow, and this deformation may lead to mechanical failure in the IC package assembly and/or failure of the reflow process.

Various ones of the embodiments disclosed herein include design features to facilitate the formation of a desired temperature profile within an IC package support structure, while limiting the likelihood of mechanical failure and achieving successful reflow. IC package support structures including one or more of these design features may exhibit advantageous thermal properties (e.g., a uniform temperature profile) and may be readily manufactured.

In the following detailed description, reference is made to the accompanying drawings that form a part hereof wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale.

FIG. 1 is a side cross-sectional view of an IC package assembly 120 including IC packages 100-1 and 100-2 disposed on an IC package support structure 106, in accordance with various embodiments. The IC package support structure 106 may include one or more heater traces 114. As discussed in detail below, the heater traces 114 of the IC package support structure 106 may be used to facilitate a local reflow temperature for the attachment/detachment of the IC packages 100. In some embodiments, the IC package assembly 120 may include one or more heat spreaders, thermal interface material (TIM), or other thermal management components, such as a heat sink or a liquid cooling system (not shown). These thermal management components may be coupled to the IC package 100 or the IC package support structure 106, for example.

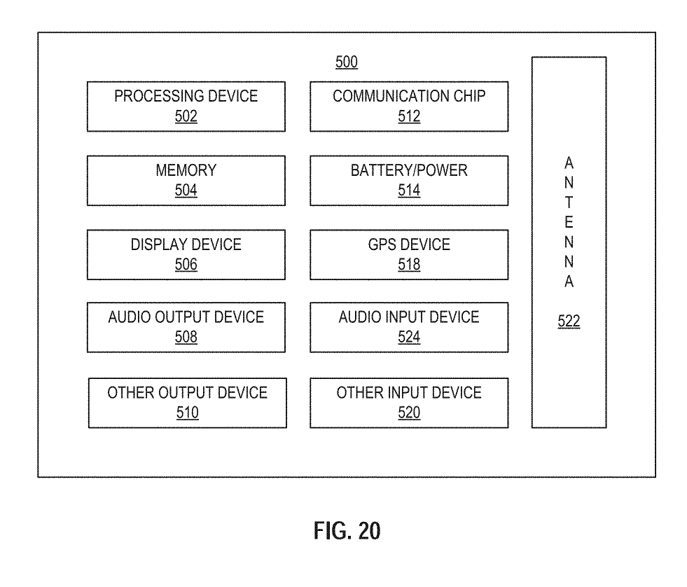

The IC packages 100-1 and 100-2 may be ball grid array (BGA) packages and may include conductive contacts 102-1 and 102-2, respectively, that are coupled to conductive contacts 110-1 and 110-2 of the IC package support structure 106 via solder 104-1 and 104-2, respectively. Each IC package 100 may include one or more IC dies (not shown) in electrical communication with the IC package support structure 106 via the conductive contacts 102. The IC dies may have their own conductive contacts coupled to the conductive contacts 102 (e.g., via flip chip or wire bonding to an IC package substrate). An IC die included in an IC package 100 may include any suitable computing component, such as a central processing unit (CPU), graphics processing unit (GPU), any other processing device, a memory device, passive components, or any combination of computing components. For example, the IC package 100 may include any suitable ones of the components discussed below with reference to the computing device 500 of FIG. 20. In some embodiments, the IC packages 100 may include an underfill material or an overmold material, or may otherwise take the form of any IC packages known in the art.

The IC package support structure 106 may include one or more heater traces 114. The heater traces 114 of the IC package support structure 106 may be proximate to vias (not shown) coupled to the conductive contacts 110, and may be arranged such that, when power is selectively dissipated in one or more of the heater traces 114, the heater traces 114 generate heat conducted by the vias to the conductive contacts 110 to cause the solder 104-1 or 104-2 disposed on the conductive contacts 110-1 or 110-2 to melt, enabling the attachment and/or detachment of the IC packages 100-1 or 100-2, respectively. Different ones of the heater traces 114 (e.g., the heater traces 114-1, 114-2, and 114-3) may be provided with power to melt solder 104 disposed on different groupings of the conductive contacts 110; for example, the heater traces 114 may generate heat to melt the solder 104-1 disposed on the conductive contacts 110-1, but not the solder 104-2 disposed on the conductive contacts 110-2, or vice versa.

The heat generated by the heater traces 114 may particularly heat particular vias (not shown for clarity of illustration, but discussed below) in the IC package support structure 106 that couple to the conductive contacts 110, thereby heating the conductive contacts 110. In FIG. 1, the IC package support structure 106 includes heater traces 114-1, 114-2, and 114-3, but the specific number of heater traces 114 shown in FIG. 1 is simply illustrative, and more or fewer heater traces 114 may be included in the IC package support structure 106. Additionally, the specific arrangement of heater traces 114 shown in FIG. 1 is simply illustrative, and any suitable arrangement may be used. The amount of power provided to the heater traces 114 to melt the solder 104 on a particular set of conductive contacts 110 may depend on the particular temperature to be achieved to melt the solder 104 (which may depend on the solder material), the arrangement of the heater traces 114, and thermal constraints on other portions of the IC package support structure 106 (e.g., other conductive contacts 110 having solder 104 that is not to be melted), for example.

In some embodiments, the IC package support structure 106 may include one or more temperature sensor traces 112. In FIG. 1, for example, the IC package support structure 106 includes temperature sensor traces 112-1 and 112-2. Each temperature sensor trace 112 may be formed of an electrically conductive material (e.g., a metal, such as copper) whose electrical resistance changes as a function of the equivalent temperature of the temperature sensor trace 112. As used herein, the “equivalent temperature” may represent a weighted average of the temperature of a temperature sensor trace 112; for example, if 90% of the length of a constant width temperature sensor trace 112 is 10° and the remaining 10% of the length of the temperature sensor trace 112 is 20°, the equivalent temperature for the temperature sensor trace 112 may be 11°. The function relating electrical resistance and equivalent temperature may be given by:

R=Rref(1+α(T−Tref))

where R is the electrical resistance of the temperature sensor trace 112 at the equivalent temperature T, Rref is a reference electrical resistance of the temperature sensor trace 112 at a reference temperature Tref, and α is the temperature coefficient of resistance for the material forming the temperature sensor trace 112. The values of α, Rref, and Tref may be experimentally determined or may be known in the art, and are accordingly not discussed further herein. When α, Rref, and Tref are known for a particular temperature sensor trace 112, a measurement of the electrical resistance R of the temperature sensor trace 112 may enable the equivalent temperature T of the temperature sensor trace 112 to be determined in accordance with the above function. The values of α, Rref, and Tref may be stored in a memory device (e.g., in a lookup table) and may be accessed as desired. In some embodiments, functions other than the function given above may more accurately describe the relationship between electrical resistance R and equivalent temperature T of a temperature sensor trace 112 (e.g., as determined experimentally); in such embodiments, the parameters of the more accurate function may be stored in a memory device (e.g., in a lookup table) and used to determine the equivalent temperature T based on the electrical resistance R. In some embodiments, Tref and Rref measurements may be taken during an initialization phase of the control hardware monitoring the temperature sensor trace 112.

In some embodiments, the temperature data provided by the resistance of the temperature sensor traces 112 may be used by a heater control device 130 (discussed below with reference to FIGS. 4-5 and 17) when providing power to the heater traces 114 in order to achieve particular temperatures at one or more locations in the IC package support structure 106. For example, the temperature sensor traces 112 of the IC package support structure 106 may be used to measure the equivalent temperature near the conductive contacts 110, and that temperature may be provided to a feedback loop in the heater control device 130 to control the amount of power provided to the heater traces 114 to achieve a desired solder-melting temperature at the conductive contacts 110. The “amount” of power may be quantified by the duty cycle settings of a pulse width modulated (PWM) current or voltage signal, the AC root-mean-square (RMS) or DC value of a current or voltage signal, or a combination thereof, for example.

The feedback loop may also be used to ensure that other portions of the IC package support structure 106 do not exceed a maximum temperature and/or the temperature across the IC package support structure 106 is relatively uniform to mitigate any mechanical failures that may occur as a result of thermal expansion mismatches. The specific number of temperature sensor traces 112 shown in FIG. 1 is simply illustrative, and more or fewer temperature sensor traces 112 may be included in the IC package support structure 106. Additionally, the specific arrangement of temperature sensor traces 112 shown in FIG. 1 is simply illustrative, and any suitable arrangement may be used. In some embodiments, no temperature sensor traces 112 may be included in the IC package support structure 106.

The IC package support structure 106 may include multiple layers 108 (in particular, layers 108-1 through 108-9). One or more of these layers 108 may include one or more heater traces 114 and/or temperature sensor traces 112. For example, in the embodiment illustrated in FIG. 1, the layer 108-2 includes two temperature sensor traces 112-1 and 112-2, the layer 108-4 includes two heater traces 114-1 and 114-2, and the layer 108-8 includes a heater trace 114-3. Different layers including heater traces 114 and/or temperature sensor traces 112 may be spaced apart by insulator layers (e.g., the layers 108-3, 108-5, and 108-7 of FIG. 1). Some of the layers 108 may be metal layers that include signal routing traces, and some of the layers 108 may be insulator layers (e.g., formed of a dielectric material) that include vias to electrically couple different metal layers, as known in the art. For example, the layer 108-1 may be an insulator layer that includes vias (not shown) to route signals to/from the conductive contacts 110. Signal routing traces and vias are not shown in FIG. 1 for ease of illustration, and may be formed in accordance with any technique known in the art. In some embodiments, the IC package support structure 106 may include multiple metal layers separated from one another by layers of dielectric material and interconnected by electrically conductive vias. Any one or more of the metal layers may be formed in a desired circuit pattern of signal routing traces to route electrical signals (optionally in conjunction with other metal layers) between the components of the IC package support structure 106. In some embodiments, a layer 108 of the IC package support structure 106 may include both signal routing traces and one or more heater traces 114 and/or temperature sensor traces 112. For example, the layers 108-2, 108-4, and/or 108-8 may include signal routing traces. In other embodiments, signal routing traces, heater traces 114, and/or temperature sensor traces 112 may be segregated in different layers 108.

In some embodiments, the IC package support structure 106 may include one or more metal planes 115. For example, FIG. 1 illustrates a metal plane 115-1 that spans all of the layer 108-6 and a metal plane 115-2 that “shares” the layer 108-8 with the heater trace 114-3. The metal planes 115 included in the IC package support structure 106 may act as heat spreaders and may help to achieve a uniform temperature profile across the IC package support structure 106. As noted above, a uniform temperature profile may reduce the likelihood of cracking, delamination, or other mechanical failures that may arise as a result of mismatches in the coefficient of thermal expansion between different materials included in the IC package assembly 120. The metal planes 115 included in the IC package support structure 106 may include holes (not shown) through which vias may extend (and from which the vias may be electrically insulated) as part of the signaling network in the IC package support structure 106. The metal planes 115 may be distinguished from metal planes that are sometimes included in conventional substrates for providing power or ground references; the metal planes 115 may not be conductively coupled to power or ground contacts of the IC package support structure 106.

When a metal plane 115 shares a layer 108 with a heater trace 114, the thickness of the metal plane 115 may be constrained to be the same as the thickness of the heater trace 114. As the thickness of a heater trace 114 increases, the resistance of the heater trace 114 decreases, and thus more current is required for the heater trace 114 to generate a desired amount of heat. Thus, in embodiments in which a metal plane 115 is desired with a thickness greater than a tolerable thickness for a heater trace 114 with which the metal plane 115 shares a layer 108, the metal plane 115 may be implemented by two or more metal planes 115 in adjacent layers 108.

The IC package support structure 106 may be formed of an epoxy resin, a fiberglass-reinforced epoxy resin, a ceramic material, or a polymer material such as polyimide. For example, when the IC package support structure 106 includes a printed circuit board (PCB), the IC package support structure 106 may include an insulating material (e.g., a glass epoxy, such as FR-4) on which a metal foil (e.g., a copper foil) is laminated and patterned via etching (or a metal is plated in a desired pattern) to provide the heater traces 114 and/or the temperature sensor traces 112; different ones of the layers 108 may each include such insulating material with a patterned metal on top. In some implementations, the IC package support structure 106 may be formed of alternate rigid or flexible materials, such as silicon, germanium, and other group III-V and group IV materials. The IC package support structure 106 may include metal interconnects and vias (not shown), including but not limited to through-silicon vias (TSVs). When the IC package support structure 106 includes a PCB, the vias may be provided by plated through-holes formed by drilling holes through metal pads on opposite faces of the insulating material, then plating the inner surface of the hole with additional metal. The IC package support structure 106 may further include embedded devices (not shown), including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical system (MEMS) devices may also be formed on the IC package support structure 106.

In some embodiments, the heater traces 114 and/or the temperature sensor traces 112 in the IC package support structure 106 may have connection terminals (not shown) exposed at a surface of the IC package support structure 106 at which a heater control device 130 (discussed below with reference to FIGS. 4-5 and 17) may make electrical contact with the heater traces 114 (to provide power to the heater traces 114 to cause the heater traces 114 to generate heat) and/or with the temperature sensor traces 112 (to measure their electrical resistance and determine their equivalent temperatures).

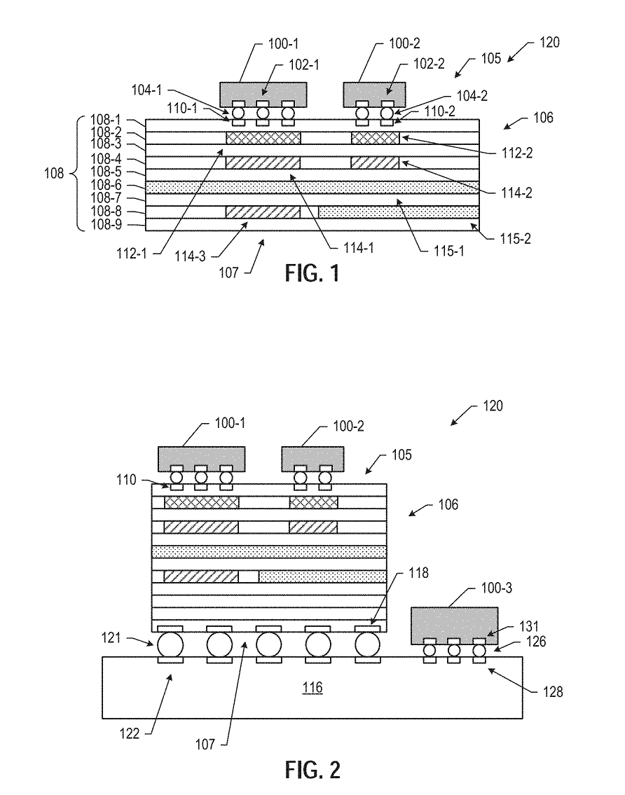

In some embodiments, the IC package support structure 106 may take the form of an interposer. For example, FIG. 2 is a side cross-sectional view of an embodiment of the IC package assembly 120 of FIG. 1 in which the IC package support structure 106 is an interposer, in accordance with various embodiments. The IC package support structure 106 may include conductive contacts 118 disposed at a first face 107 of the IC package support structure 106, and the conductive contacts 110 may be disposed at a second face 105 of the IC package support structure 106. The conductive contacts 118 may be coupled to conductive contacts 122 of a PCB 116 via solder 121, and the conductive contacts 110 may be coupled to the IC packages 100, as discussed below with reference to FIG. 5. Additional IC packages, such as the IC package 100-3 of FIG. 2, may be coupled to the PCB 116. The IC package 100-3 may take the form of any of the IC packages 100 disclosed herein and may include conductive contacts 131 coupled to conductive contacts 128 of the PCB 116 via solder 126. In some embodiments, the PCB 116 may be a motherboard or other suitable substrate. The IC package support structure 106 of FIG. 2 may include electrical signal routing traces and vias arranged to route electrical signals between the conductive contacts 110 and the conductive contacts 122 via the conductive contacts 118. The components of the IC package support structure 106 of FIG. 2 may take the form of any of the embodiments of the IC package support structure 106 discussed above with reference to FIG. 1. Note that the interposer of FIG. 2 may itself be a PCB, and may be manufactured in accordance with PCB design rules and with PCB materials.

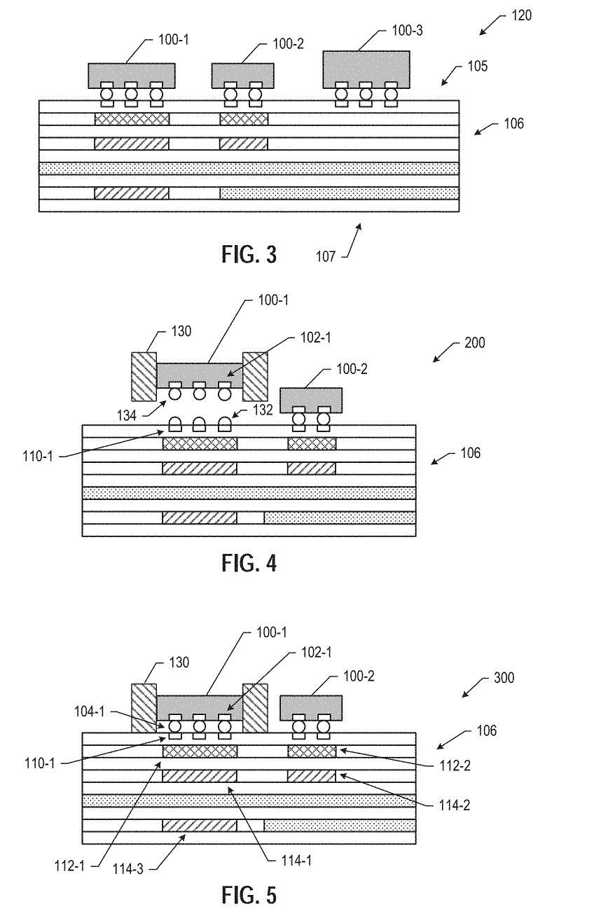

In some embodiments, the IC package support structure 106 may take the form of a PCB (e.g., a motherboard). FIG. 3 is a side cross-sectional view of an embodiment of the IC package assembly 120 of FIG. 1 in which the IC package support structure 106 is a PCB having the IC packages 100-1, 100-2, and 100-3 disposed thereon, in accordance with various embodiments. The components of the IC package support structure 106 of FIG. 3 may take the form of any of the embodiments of the IC package support structure 106 discussed above with reference to FIG. 1.

As noted above, the heater traces 114 included in the IC package support structure 106 may be used to facilitate the attachment and detachment of one or more of the IC packages 100 from the IC package support structure 106. FIG. 4 is a side cross-sectional view of an assembly 200 subsequent to bringing a heater control device 130 and an IC package 100-1 in proximity to the IC package support structure 106 of FIG. 1, in accordance with various embodiments. In some embodiments, the heater control device 130 may include a mechanical clamp or other structure to hold the IC package 100-1, and may also include alignment features (e.g., alignment corners, pins) to facilitate the alignment of the heater control device 130 (while holding the IC package 100-1) into a desired position on the IC package support structure 106. Solder balls 134 may be disposed on the conductive contacts 102-1 of the IC package 100-1, and solder paste 132 may be disposed on the conductive contacts 110-1. Proper alignment of the heater control device 130 (and IC package 100-1) with the IC package support structure 106 may align the conductive contacts 102-1 with corresponding conductive contacts 110-1, may align heater trace contacts (not shown) of the heater control device 130 with connection terminals (not shown) of the heater traces 114, and may align temperature sensor trace contacts (not shown) of the heater control device 130 with connection terminals (not shown) of the temperature sensor traces 112.

FIG. 5 is a side cross-sectional view of an assembly 300 subsequent to using the heater control device 130 of FIG. 4 to couple the IC package 100-1 to the IC package support structure 106, in accordance with various embodiments. In particular, once the heater control device 130 and the IC package 100-1 are properly aligned with the IC package support structure 106, the heater control device 130 may cause power to be dissipated in the heater traces 114 of the IC package support structure 106 to melt the solder balls 134 and the solder paste 132 to conductively couple the conductive contacts 102-1 of the IC package 100-1 to the conductive contacts 110-1 of the IC package support structure 106. As discussed above, in some embodiments, the heater control device 130 may use temperature feedback from the temperature sensor traces 112 to adjust the amount of power provided to the heater traces 114 to achieve a desired temperature profile in the IC package support structure 106. Once the solder balls 134 and the solder paste 132 have achieved desired reflow conditions, the heater control device 130 may allow the heater traces 114 to cool, thereby allowing the solder 104 between the conductive contacts 102-1 and the conductive contacts 110-1 to solidify. The heater control device 130 may then disengage from the IC package 100-1 and the IC package support structure 106.

If the IC package 100-1 is to be detached from the IC package support structure 106, an analogous procedure may be performed: the heater control device 130 may be brought into alignment with the IC package 100-1 and the IC package support structure 106, power may be selectively provided to the heater traces 114 to cause the solder 104-1 to melt, and the IC package 100-1 may be removed.

In some embodiments, the heater control device 130 may be temporarily coupled to the IC package 100-1, and may be disengaged from the IC package 100-1 when attachment/detachment of the IC package 100-1 is not under way. For example, the heater control device 130 may be a reusable, modular device that can be used in the field or in a factory setting. Such a heater control device 130 may be designed for use with one particular IC package design or may be usable with multiple different IC package designs. In other embodiments, the heater control device 130 may be permanently coupled to the IC package 100-1. In some embodiments, the heater control device 130 may be temporarily coupled to the IC package support structure 106 and may be disengaged from the IC package support structure 106 when attachment/detachment of the IC package 100-1 is not under way. In other embodiments, the heater control device 130 may be permanently coupled to the IC package support structure 106.

In some embodiments, the heater control device 130 may include its own power source to drive the heater traces 114, while in other embodiments, the heater control device 130 may utilize a power source included in the IC package support structure 106 or the PCB 116.

By facilitating the attachment/detachment of the IC package 100-1, the IC package support structure 106 may improve on conventional attachment methodologies. Such conventional attachment methodologies include conventional BGA attachment, in which an IC package is soldered to a component. Conventional BGA attachment typically exhibits high reliability and good high-speed signaling performance, but must be reworked in a controlled factory setting with specialized equipment and training, and therefore BGA packages are not readily attached and detached during testing or in the field. Another example of a conventional attachment methodology is a land grid array (LGA), in which an IC package is fitted into a socket. IC packages with LGA connections are readily attached and detached, but LGA sockets are prone to damage (and are themselves not readily replaced), and may exhibit poor high-speed signal performance (e.g., by adding impedance and cross talk to the signal chain). Another example of a conventional attachment methodology is metal particle interconnect (MPI), another socket methodology. Conventional MPI sockets are too expensive to be suited for high-volume production, and may add impedance to the signal chain.

The IC package support structure 106 may provide the advantages of conventional BGA attachment by facilitating a direct solder connection between the IC package support structure 106 and the IC package 100-1, while facilitating easy attachment/detachment by the use of the heater traces 114 (achieving or surpassing the ease of sockets). When the heater control device 130 is a modular component, a technician in the factory or field can readily install or replace the IC package 100-1.

The layout and arrangement of heater traces 114 among one or more layers 108 of an IC package support structure 106 will affect the temperature profile of the IC package support structure 106 when power is provided to the heater traces 114. In some embodiments, it may be desirable to controllably produce a uniform temperature profile across the conductive contacts 110 coupled to an IC package 100, and/or across the IC package support structure 106, and/or across the IC package assembly 120. Temperature uniformity across the conductive contacts 110 may ensure consistent and effective reflow of the solder 104 when the IC package 100 is being attached/detached. Using the heater traces 114 to achieve temperature uniformity within the IC package support structure 106 may mitigate the nonuniform thermal losses experienced by different portions of the IC package support structure 106 (with large heat losses experienced by power/ground signal planes, lesser heat losses experienced by signal routing traces, and even lesser heat losses experienced by test pins and unused features). Temperature uniformity within the IC package assembly 120 may minimize the likelihood of a mechanical failure due to warpage caused by thermal mismatch of different components in the IC package assembly 120.

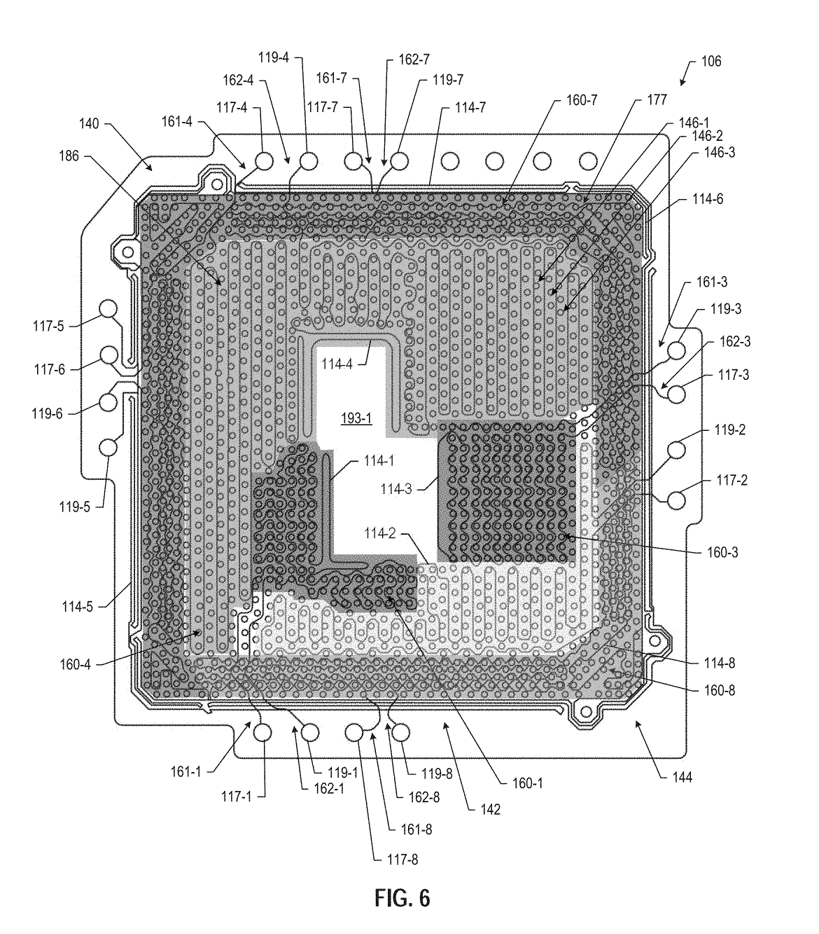

Disclosed herein are a number of heater trace design features that may be included in various embodiments of the IC package support structure 106 to achieve various thermal management objectives. In particular, the heater trace design features, and associated manufacturing techniques, may help the IC package support structure 106 achieve more localized heat delivery and/or deliver greater amounts of heat than could be achieved using conventional features and manufacturing techniques. It will be noted that the examples of FIGS. 6-16 include a number of design features that may not be explicitly discussed in the body of this specification for ease of illustration, but one of ordinary skill in the art will recognize the presence of these design features. As noted above, the IC package support structure 106 may, in various embodiments, be an interposer, a motherboard, or any other suitable component.

Although heater traces 114 are discussed below with reference to FIGS. 6-16, any of the heater traces 114 disclosed herein may be used as temperature sensor traces 112 (e.g., by measuring the resistance of the heater trace 114, as discussed above). In particular, any individual heater trace 114 may be used alternately as both a heater trace and the temperature sensor trace (e.g., by alternately providing power to the trace and measuring the resistance of the trace). Thus, any of the heater trace designs disclosed herein may also be used as temperature sensor trace designs.

FIG. 6 is a top view of a stack of heater traces 114 disposed in multiple layers 108 of the IC package support structure 106. In particular, the embodiment of FIG. 6 includes heater traces 114-1, 114-2, 114-3, 114-4, 114-5, 114-6, 114-7, and 114-8. None of the heater traces 114 illustrated in FIG. 6 are conductively coupled to each other in the IC package support structure 106, and each of the heater traces 114 has a first connection terminal 117 and a second connection terminal 119. In the embodiment of FIG. 6, all of the connection terminals 117 and 119 are disposed in a perimeter region 140 of the IC package support structure 106. The central region 186 of the IC package support structure 106 may include vias 177, which may be coupled to corresponding ones of the conductive contacts 110. As discussed above with reference to FIGS. 1-5, the conductive contacts 110 may be used to couple the IC package support structure 106 to one or more IC packages 100 (e.g., BGA IC packages 100). In the IC package support structure 106 of FIG. 6 (and the other IC package support structures disclosed herein), heat generated by different ones of the heater traces 114 may be absorbed by proximate ones of the vias 177 and conducted to corresponding ones of the conductive contacts 110 to cause reflow of the solder 104, as discussed above.

In some embodiments of the IC package support structures 106 disclosed herein, some of the heater traces 114 may be disposed in the perimeter of the IC package support structure 106, while other heater traces 114 may be disposed in a central region of the IC package support structure 106. For example, in FIG. 6, the heater traces 114-5 and 114-6 are also disposed in the perimeter region 140, while the heater traces 114-1, 114-2, 114-3, and 114-4 are disposed in a central region 186. In particular, the heater trace 114-6 wraps around the central region 186, and most of the length of the heater trace 114-6 is disposed at the corners 144 of the IC package support structure 106 (with some of the length of the heater trace 114-6 disposed along the edges 142 of the IC package support structure 106). The heater trace 114-5 also wraps around the central region 186, and most of the length of the heater trace 114-5 is disposed along the edges 142 of the IC package support structure 106 (with some of the length of the heater trace 114-5 disposed at the corners 144 of the IC package support structure 106). In the embodiment illustrated in FIG. 6, neither the heater trace 114-5 nor the heater trace 114-6 extend into the central region 186.

Different ones of the heater traces 114 included in an IC package support structure 106 may have different footprints. For example, in FIG. 6, the heater trace 114-1 has a footprint 160-1 shaped substantially like an “L,” with a first connection terminal extension 161-1 and a second connection terminal extension 162-1 extending from the footprint 160-1 to the connection terminals 117-1 and 119-1, respectively. The heater trace 114-3 has a convex footprint 160-3 (in particular, a rectangular footprint) with a first connection terminal extension 161-3 and a second connection terminal extension 162-3 extending from the footprint 160-3 to the connection terminals 117-3 and 119-3, respectively. The heater trace 114-4 has a footprint 160-4 with a first connection terminal extension 161-4 and a second connection terminal extension 162-4 extending from the footprint 160-4 to the connection terminals 117-4 and 119-4, respectively. The heater traces 114-5 and 114-6 do not have their footprints labeled in FIG. 6, but as discussed above, each extends around the perimeter region 140 of the IC package support structure 106. The heater trace 114-7 has a footprint 160-7 shaped substantially like a “U,” with a first connection terminal extension 161-7 and a second connection terminal extension 162-7 extending from the footprint 160-7 to the connection terminals 117-7 and 119-7, respectively. The heater trace 114-8 has footprint 160-8 shaped substantially like an “L,” with a first connection terminal extension 161-8 and a second connection terminal extension 162-8 extending from the footprint 160-8 to the connection terminals 117-8 and 119-8, respectively.

Heater traces 114 arranged in a regular pattern and having a convex footprint 160 (e.g., a rectangle) may help the IC package support structure 106 achieve a more uniform temperature than heater traces 114 having highly irregular footprints 160. Thus, for example, it may be advantageous to minimize the number of “openings” in the footprint 160 of a heater trace 114 through which other heater traces 114 extend. In particular, in some embodiments, a footprint 160 of a heater trace 114 may have no openings or only a single opening. At the same time, it may be useful to have different heater traces 114 corresponding to different features in the IC package 100 in order to provide independently controllable heat for each of these different features. Selecting an appropriate arrangement for the heater traces 114 may be a balancing of these design features, as understood by one of skill in the art.

A design feature exhibited by the heater traces 114-1, 114-3, and 114-4 of FIG. 6 is the routing of a portion of the heater traces 114 outside of the area of the vias 177 and along the edges of the area 193-1 in which no vias 177 are disposed. These extra lengths of the heater traces 114 may mitigate the thermal gradient that forms in the IC package support structure 106 as one gets farther away from the vias 177, by generating additional heat to smooth the gradient. Generally, it may be advantageous to minimize the lengths of the connection terminal extensions 161 and 162 (between the connection terminals 117/119 and the footprint 160) for each heater trace 114, so as not to dissipate power (in the form of heat) in areas that have not been targeted for heating.

The footprints of different ones of the heater traces 114 included in different layers 108 of the IC package support structure 106 may overlap, or may not overlap. For example, in FIG. 6, the footprints 160 of the heater traces 114 do not overlap, although various ones of the connection terminal extensions 161 and 162 overlap with various ones of the footprints 160.

In some embodiments, when a heater trace 114 in one layer 108 “overlaps” a heater trace 114 in another layer 108, the overlapping portion of the heater traces 114 may have a greater width than the remainder of the heater traces 114. For example, the connection terminal extensions 161-3 and 162-3 of the heater trace 114-3 of FIG. 6 “overlaps” with the footprint 160-7 of the heater trace 114-7; in some embodiments, the connection terminal extensions 161-3 and 162-3 may have a width that is thicker than the width of the remainder of the heater trace 114-3 (e.g., by 1-5 mils). The width of the heater traces 114 may be limited by the pitch of the conductive contacts 110/vias 177, but increasing the width of a heater trace 114 in an overlap area may reduce the power dissipated by the thickened section of the heater trace 114 relative to the non-thickened section, preventing the formation of a hot spot where two heater traces 114 overlap.

In some embodiments of the IC package support structure 106 disclosed herein, a heater trace 114 may “wind” between adjacent parallel rows of vias 177. For example, in FIG. 6, the conductive contacts 110 include a first row 146-1 of vias 177, a second row 146-2 of vias 177, and the third row 146-3 of vias 177. The heater trace 114-4 is disposed between the first row 146-1 and the second row 146-2, and between the second row 146-2 and the third row 146-3. When heating an area of the IC package support structure 106, it may be advantageous to wind a heater trace 114 between adjacent vias 177, without “skipping” adjacent rows, to achieve a uniform temperature profile.

The density of vias 177 in a layer 108 of the IC package support structure 106 may vary across the layer 108. For example, in the embodiment of FIG. 6, the density of vias 177 proximate to the heater trace 114-1 (e.g., in the footprint 160-1 of the heater trace 114-1) is greater than the density of vias 177 proximate to the heater trace 114-4 (e.g., in the footprint 160-4 of the heater trace 114-4). As used herein, the “density” of vias 177 or conductive contacts 110 may refer to the percentage of area occupied by vias 177 or conductive contacts 110 in the layer 108 or the second face 105, respectively, of the IC package support structure 106. Because the vias 177 correspond to conductive contacts 110 on the surface of the IC package support structure 106, and because heat may dissipate into the ambient environment from the conductive contacts 110, the IC package support structure 106 may experience greater thermal loss in regions with greater density of vias 177. Consequently, in some embodiments, the heater control device 130 may deliver more power to heater traces 114 in regions of higher density of vias 177. For example, the heater control device 130 may deliver more power to the heater trace 114-1 than to the heater trace 114-4.

In some embodiments of the IC package support structure 106 disclosed herein, different ones of multiple heater traces 114 may be disposed in a common layer 108, and/or in different layers 108. For example, the heater traces 114-1, 114-2, 114-3, and 114-4 may be included in a common layer 108, the heater traces 114-5 and 114-6 may be included in a common layer 108 (different from the layer 108 including the heater traces 114-1, 114-2, 114-3, and 114-4), and the heater traces 114-7 and 114-8 may be included in a common layer 108 (different from the layer including the heater traces 114-1, 114-2, 114-3, and 114-4, and different from the layer including the heater traces 114-5 and 114-6).

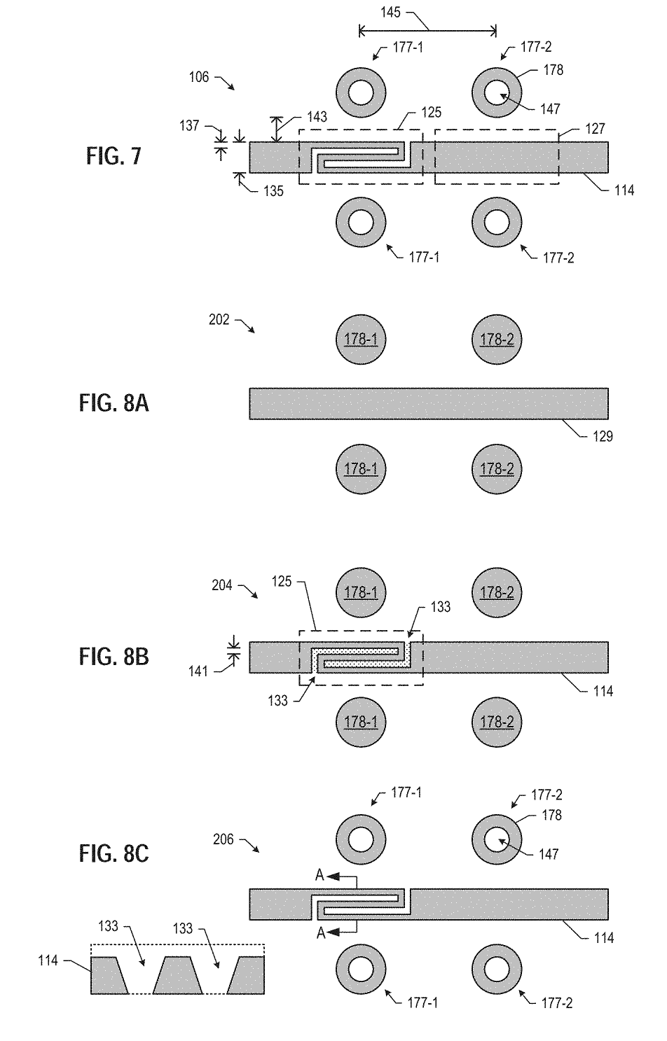

FIGS. 7, 9, 11, 13, and 15 illustrate different patterns of conductive material that may be included in a layer 108 of an IC package support structure 106, in accordance with various embodiments. In particular, FIGS. 7, 9, 11, 13, and 15 represent “top” views of various patterns of conductive material (e.g., heater traces 114 and metal planes 115) that may be formed on an insulating material (e.g., a dielectric material, such as a glass epoxy or other material in a PCB) as part of a layer 108 of an IC package support structure; the insulating material is not shown in FIGS. 7, 9, 11, 13, and 15 for clarity of illustration. Any of the heater traces 114 or metal planes 115 discussed above with reference to FIGS. 1-6 may include or take the form of any of the heater traces 114 or metal planes 115, respectively, discussed below with reference to FIGS. 7-16.

Various ones of the design features illustrated in FIGS. 7-16 may improve the solder flow reliability when solder 104 is melted on the second face 105 of the IC package support structure 106 to remove or place one or more IC packages 100. As noted above, when current flows through the heater traces 114 in the IC package support structure 106 to generate heat and create a local solder reflow temperature profile, the vias 177 (which may take the form of pins) may be nonuniformly heated due to the different thermal termination condition of each via 177. For example, vias 177 that provide power/ground to the IC packages 100 may be thermally coupled to large power/ground conductive regions in a system board (e.g., a motherboard or other PCB 116); these large power/ground conductive regions may act as good heat sinks. By contrast, vias 177 that provide electrical signals to/from the IC packages 100 may be thermally coupled to more narrow traces in the system board; these narrower traces may act as poorer heat sinks. As a result, the power/ground vias 177 (“cold pins”) may sink more heat (and thus may exhibit a smaller increase in temperature) than signal vias 177 (“hot pins”) in response to a same input of heat from a heater trace 114. This nonuniform thermal profile may lead to a nonuniform solder flow profile, which may cause reliability issues during detachment/attachment of an IC package 100 to the IC package support structure 106.

Various ones of the design features illustrated in FIGS. 7-16 may improve the dynamic heating power range achievable by a heater trace 114 to equalize an otherwise nonuniform thermal profile (e.g., by dissipating higher power near cold pins and lower power near hot pins) to achieve a substantially uniform solder reflow temperature across all pins.

Various ones of the manufacturing techniques discussed below with reference to FIGS. 7-16 may involve performing non-conventional conductive material modifications after conventional PCB manufacturing techniques have been performed. These non-conventional modifications may overcome the limitations on the structure of heater traces 114 resulting from conventional design rules imposed by the limitations of the manufacturing processes used to fabricate the heater traces 114, and thus achieving a greater range of thermal compensation capability than could be previously achieved. For example, the embodiments disclosed herein may achieve features that are smaller and/or closer than achievable in accordance with low density interconnect (LDI) design rules for PCG manufacturing.

FIG. 7 is a top view of a layer 108 in an IC package support structure 106 including a heater trace 114 with a narrowed section 125, in accordance with various embodiments. The heater trace 114 is illustrated as extending between two pairs of vias 177: a pair of vias 177-1, and a pair of vias 177-2. The narrowed section 125 is disposed between the vias 177-1, and another, wider section 127 of the heater trace 114 is disposed between the vias 177-2. The vias 177 illustrated in FIG. 7 (and elsewhere herein) may take the form of plated through-holes, and may include conductive pads 178 with a plated opening 147 extending between conductive pads 178 on opposing faces of an insulating material (not shown). The heater trace 114 illustrated in FIG. 7 may be a section of a larger heater trace 114, and the remainder of that larger heater trace 114 may take any of the forms disclosed herein (e.g., may include any of the narrowed sections 125 or other features disclosed herein).

The wider section 127 of the heater trace 114 may have a width 135, and the narrowed section 125 of the heater trace 114 may have a width 137 that is smaller than the width 135. When a current is conducted through the heater trace 114, the amount of power dissipated at a point along the heater trace 114 will be inversely proportional to the cross-sectional area of the heater trace 114 at that point. Thus, wider sections of the heater trace 114 may dissipate less power (in the form of heat) than narrower sections. In the embodiment illustrated in FIG. 7, when current flows through the heater trace 114, the narrowed section 125 will dissipate more heat than the wider section 127, and thus the vias 177-1 (proximate to the narrowed section 125) will be heated more than the vias 177-2 (proximate to the wider section 127). When the vias 177-1 are “cold pins” and the vias 177-2 are “hot pins,” the localized heating achievable by the heater trace 114 of FIG. 7 may improve the uniformity of the temperature profile across the vias 177.

The width 135 of the heater trace 114 in the wider section 127 may be controlled by the design rules of the technology used to fabricate the IC package support structure 106. In particular, when the IC package support structure 106 includes a PCB, and PCB tools and techniques are used to form the heater trace 114 and the vias 177, various dimensions of the heater trace 114 and the vias 177 may be constrained by the design rules of PCB technology. For example, the PCB design rules may specify a minimum trace width that represents the smallest manufacturable width 135 for the heater trace 114 (or any trace in the layer 108). In some embodiments, the design rule minimum trace width for a PCB may be 3.5 mils. PCB design rules may also specify dimensions other than the minimum trace width; for example, the design rules may specify a minimum pad pitch 145 (constraining how close adjacent vias 177 may be to each other) and a minimum trace-to-pad clearance 143 (constraining how close a via 177 may be to the heater trace 114). For example, a minimum trace-to-pad clearance 143 may be between 3.5 mils and 4 mils (which may also be a minimum pad-to-pad clearance). A minimum pad pitch 145 may be between 0.7 millimeters and 1 millimeter (depending, e.g., on the solder ball that will be reflowed onto the pad). Using conventional manufacturing techniques, these design rules may constrain the size and density of heater traces 114 in and around the vias 177, and limit the ability of the heater trace 114 to compensate for thermal differences between the vias 177-1 and the vias 177-2, for example.

As noted above, the width 137 of the narrowed section 125 of the heater trace 114 may be less than the width 135 of the wider section 127. Further, in some embodiments, the width 137 of the narrowed section 125 of the heater trace 114 may be less than the design rule minimum trace width, and thus heater traces 114 like the one illustrated in FIG. 7 may not be achievable using standard PCB techniques. Having sections of heater traces 114 with widths that are less than the design rule minimum trace width may enable the use of heater traces 114 that can generate more localized heat than could be generated with “wider” traces that conform to the design rules, and thus may achieve new ranges of heating performance. Various techniques for forming the heater trace 114 of FIG. 7, and other heater traces 114 disclosed herein, are discussed below.

Although the narrowed section 125 of the heater trace 114 of FIG. 7 is shown as having a particular serpentine shape, a narrowed section 125 of a heater trace 114 may have any suitable length or shape (e.g., a serpentine shape oriented in a different direction than that shown in FIG. 7, a spiral shape, a straight line, a shape with non-right angles, etc.). Additionally, although a single narrowed section 125 is illustrated in FIG. 7, any of the heater traces 114 disclosed herein may include multiple narrowed sections 125 (which may have the same or different dimensions and shapes relative to each other), as well as multiple wider sections 127. Further, although the narrowed section 125 of the heater trace 114 of FIG. 7 is shown as having a substantially uniform width 137 along the contours of its serpentine shape, a narrowed section 125 may have a width that varies along its length in any desired manner, and similarly, a wider section 127 may have a width that varies along its length in any desired manner.

FIGS. 8A-8C illustrate various stages in the manufacture of the layer 108 of FIG. 7, in accordance with various embodiments. In particular, FIGS. 8A-8C illustrate a set of techniques that may be used to form the narrowed section 125 of the heater trace 114 of FIG. 7.

FIG. 8A is a top view of the conductive material in an assembly 202, including one pair of conductive pads 178-1, one pair of conductive pads 178-2, and an initial trace 129. The assembly 202 may be formed using conventional PCB manufacturing techniques, and thus may be subject to conventional PCB manufacturing design rules (e.g., the minimum trace width, minimum pad pitch, and minimum trace-to-pad clearance discussed above with reference to FIG. 7). In some embodiments, the assembly 202 may be formed by patterning the conductive pads 178 and the initial trace 129 on an insulating material (e.g., a glass epoxy) using a conventional additive, subtractive, or semi-additive technique. For example, in a semi-additive process, a thin layer of metal (e.g., copper) may be present on the insulating material, a resist material may be applied and lithographically patterned, additional metal may be plated on to a desired thickness, then the resist material and remaining thin copper may be stripped away to leave patterned metal behind. In a subtractive process, an insulating material is coated with metal (e.g., copper), a resist material is applied and lithographically patterned, the metal is etched in accordance with the patterned resist material, then the resist material is stripped away to leave the patterned metal behind.

FIG. 8B is a top view of the conductive material in an assembly 204, subsequent to removing at least some of the conductive material in the initial trace 129 of the assembly 202 (FIG. 8A) to form the heater trace 114. In particular, FIG. 8B illustrates two slots 133 (shown with dotted shading) representing conductive material portions of the initial trace 129 of the assembly 202 that are removed to form the heater trace 114 of the assembly 204. Any suitable technique may be used to remove the conductive material of the initial trace 129 to form the heater trace 114. In some embodiments, the slots 133 may be formed in the initial trace 129 by laser cutting (also referred to as laser micro-cutting). In such a technique, a laser beam may be directed to desired locations in the initial trace 129 to remove (e.g., melt or vaporize) the conductive material in those locations, forming the slots 133. In some embodiments in which the laser cutter is a gas-assisted laser cutter, a jet of gas may be emitted along with the laser beam to remove the molten conductive material from the cut.

In some embodiments, the width 141 of a slot 133 may be between 0.7 and 1 mil, and this width 141 may depend on the thickness of the initial trace 129. In some embodiments, laser cutting the slots 133 into the initial trace 129 will burn or vaporize the insulating material under or proximate to the slots 133, and thus the narrowed sections 125 may have burned portions of the insulating material (e.g., a burned portion of glass epoxy, such as FR-4, or other dielectric) adjacent to the narrowed sections 125. For example, burned insulating material may be located under or adjacent to a slot 133. The slots 133 illustrated in FIG. 8B each have an L-shape as viewed from above, but as noted above, the slots 133 may have any desired shape, and any desired number of slots 133 may be cut into the initial trace 129.

FIG. 8C is a top view of the conductive material in an assembly 206, subsequent to drilling and plating openings 147 in the conductive pads 178 of the assembly 204 to form the conductive vias 177. Any conventional PCB techniques may be used for these drilling and plating operations. The resulting assembly 206 may take the form of the layer 108 illustrated in FIG. 7.

FIG. 8C also includes an inset (in a dotted box) illustrating a cross-sectional view of the assembly 206 along the section A-A. As illustrated in the inset, in some embodiments, the slots 133 may have trapezoidal cross-sections that are wider on the side of the initial trace 129 on which the laser is incident. When the slots 133 do not have uniform width across their depth (e.g., when the slots 133 have a trapezoidal cross-section), the width 141 of a slot 133 may represent the width of the narrowest portion of the slot 133.

FIG. 9 is a top view of a layer 108 in an IC package support structure 106 including a heater trace 114 with multiple narrowed sections 125, in accordance with various embodiments. The heater trace 114 of FIG. 9 is illustrated as making a 90-degree “turn” around a via 177-1 so that the heater trace 114 is proximate to two “sides” of the via 177-1. Additional vias 177-2 and 177-3 are also illustrated; the heater trace 114 of FIG. 9 is proximate to one “side” of the vias 177-2, and farther from the via 177-3. Narrowed sections 125 are disposed between the via 177-1 and the via 177-2, and are between wider sections 127 along the heater trace 114. The vias 177 illustrated in FIG. 9 (and elsewhere herein) may take the form of plated through-holes, and may include conductive pads with a plated opening (not labeled in FIG. 9) extending between conductive pads on opposing faces of an insulating material (not shown). The heater trace 114 illustrated in FIG. 9 may be a section of a larger heater trace 114, and the remainder of that larger heater trace 114 may take any of the forms disclosed herein (e.g., may include any of the narrowed sections 125 or other features disclosed herein).

As discussed above with reference to FIG. 7, the wider sections 127 of the heater trace 114 may have a width 135, and the narrowed sections 125 of the heater trace 114 may have a width 137 that is smaller than the width 135. When a current is conducted through the heater trace 114, the amount of power dissipated at a point along the heater trace 114 will be inversely proportional to the cross-sectional area of the heater trace 114 at that point. Thus, in the embodiment illustrated in FIG. 9, when current flows through the heater trace 114, the narrowed sections 125 will dissipate more heat than the wider sections 127, and thus the via 177-1 will be heated more than the vias 177-2, and the vias 177-2 will be heated more than the via 177-3.

The wider sections 127 of the heater trace 114 of FIG. 9 may have any of the dimensions discussed above with reference to FIG. 7, and in particular, may be limited to be greater than or equal to a design rule minimum trace width. In some embodiments, the width 137 of the narrowed sections 125 of the heater trace 114 of FIG. 9 may be less than the design rule minimum trace width.

Although the narrowed sections 125 of the heater trace 114 of FIG. 9 are shown as having particular serpentine shapes, narrowed sections 125 of a heater trace 114 may have any suitable length or shape (e.g., any of the shapes discussed above with reference to FIG. 7). Additionally, although multiple narrowed sections 125 are illustrated in FIG. 9, any of the heater traces 114 disclosed herein may include a single narrowed section 125. Further, as noted above with reference to FIG. 7, although the narrowed sections 125 of the heater trace 114 of FIG. 9 are shown as having a substantially uniform width 137 along the contours of its serpentine shape, a narrowed section 125 may have a width that varies along its length in any desired manner, and similarly, a wider section 127 may have a width that varies along its length in any desired manner.

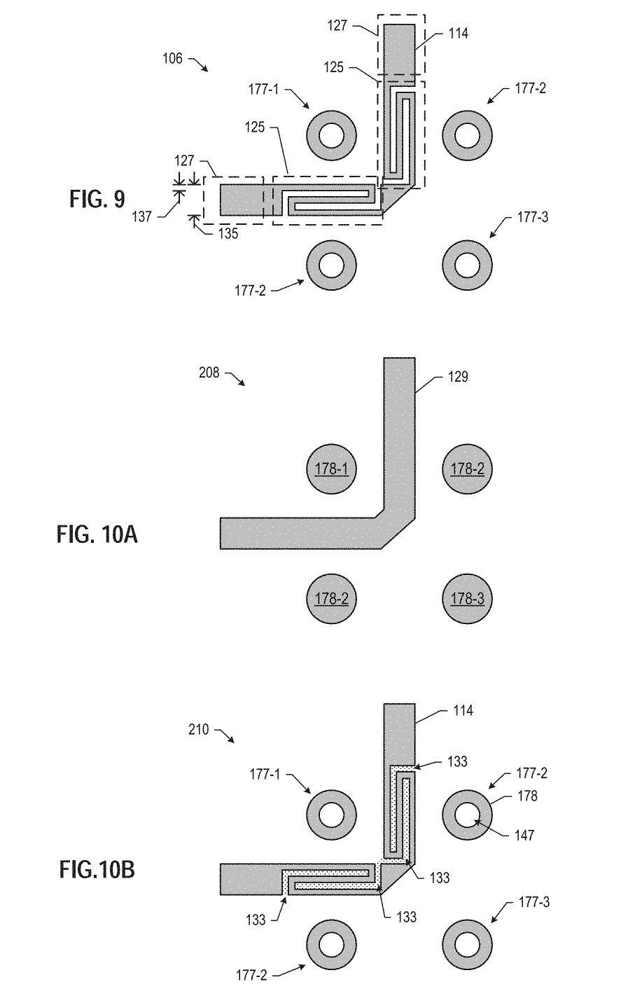

FIGS. 10A-10B illustrate various stages in the manufacture of the layer 108 of FIG. 9, in accordance with various embodiments. In particular, FIGS. 10A-10B illustrate a set of techniques that may be used to form the narrowed sections 125 of the heater trace 114 of FIG. 9.

FIG. 10A is a top view of the conductive material in an assembly 208, including a conductive pad 178-1, two conductive pads 178-2, a conductive pad 178-3 (with the conductive pads 178 arranged in a rectangular array), and an initial trace 129. The assembly 208 may be formed using conventional PCB manufacturing techniques, and thus may be subject to conventional PCB manufacturing design rules (e.g., the minimum trace width, minimum pad pitch, and minimum trace-to-pad clearance) and using conventional PCB manufacturing materials and processes (including any of those discussed above with reference to FIG. 8A).

FIG. 10B is a top view of the conductive material in an assembly 210, subsequent to removing at least some of the conductive material in the initial trace 129 of the assembly 208 (FIG. 10A) to form the heater trace 114, and drilling and plating openings 147 in the conductive pads 178 of the assembly 208 to form the conductive vias 177. In particular, FIG. 10B illustrates four slots 133 (shown with dotted shading) representing conductive material portions of the initial trace 129 of the assembly 208 that are removed to form the heater trace 114 of the assembly 210. Any suitable technique may be used to remove the conductive material of the initial trace 129 to form the heater trace 114, such as any of the techniques discussed above with reference to FIG. 8B, and the resulting slots 133 may have any of the dimensions or material properties discussed above with reference to FIG. 8B. Any conventional PCB techniques may be used for the drilling and plating operations. The resulting assembly 210 may take the form of the layer 108 illustrated in FIG. 9.

FIG. 11 is a top view of a layer 108 in an IC package support structure 106 including heater traces 114 with multiple narrowed sections 125, in accordance with various embodiments. Two heater traces 114 are depicted in FIG. 11, but a layer 108 may include any desired number of the heater traces 114. In FIG. 11, each of the heater traces 114 includes multiple wider sections 127 forming a “trunk” of the heater trace 114. Adjacent wider sections 127 are spaced apart by a narrowed section 125 forming a “branch” of the heater trace 114. In FIG. 11, the wider sections 127 are disposed between pairs of vias 177 in different horizontal rows (using the perspective of the figure) and the narrowed sections 125 are disposed between pairs of vias 177 in different vertical columns (again, using the perspective of FIG. 11). The vias 177 illustrated in FIG. 11 (and elsewhere herein) may take the form of plated through-holes, and may include conductive pads with a plated opening (not labeled in FIG. 11) extending between conductive pads on opposing faces of an insulating material (not shown). The heater traces 114 illustrated in FIG. 11 may be sections of larger heater traces 114, and the remainders of those larger heater traces 114 may take any of the forms disclosed herein (e.g., may include any of the narrowed sections 125 or other features disclosed herein). In some embodiments, the heater traces 114 illustrated in FIG. 11 may both be part of a common heater trace 114 (e.g., by being electrically coupled outside of the view of the figure).

As discussed above with reference to FIG. 7, the wider sections 127 of the heater trace 114 may have a width 135, and the narrowed sections 125 of the heater trace 114 may have a width 137 that is smaller than the width 135; in FIG. 11, these widths are labeled on only one of the heater traces 114 for economy of illustration. In the embodiment illustrated in FIG. 11, when current flows through the heater trace 114, the narrowed sections 125 will dissipate more heat than the wider sections 127.

The wider sections 127 of the heater traces 114 of FIG. 11 may have any of the dimensions discussed above with reference to FIG. 7, and in particular, may be limited to be greater than or equal to a design rule minimum trace width. In some embodiments, the width 137 of the narrowed sections 125 of the heater traces 114 of FIG. 11 may be less than the design rule minimum trace width.

Although the narrowed sections 125 of the heater trace 114 of FIG. 9 are shown as being substantially U-shaped, narrowed sections 125 of the heater traces 114 of FIG. 11 may have any suitable length or shape (e.g., any of the shapes discussed above with reference to FIG. 7). Additionally, although multiple narrowed sections 125 are illustrated in FIG. 11, any of the heater traces 114 disclosed herein may include a single narrowed section 125. Further, as noted above with reference to FIG. 7, although the narrowed sections 125 of the heater trace 114 of FIG. 11 are shown as having a substantially uniform width 137 along the contours of its shape, a narrowed section 125 may have a width that varies along its length in any desired manner, and similarly, a wider section 127 may have a width that varies along its length in any desired manner.

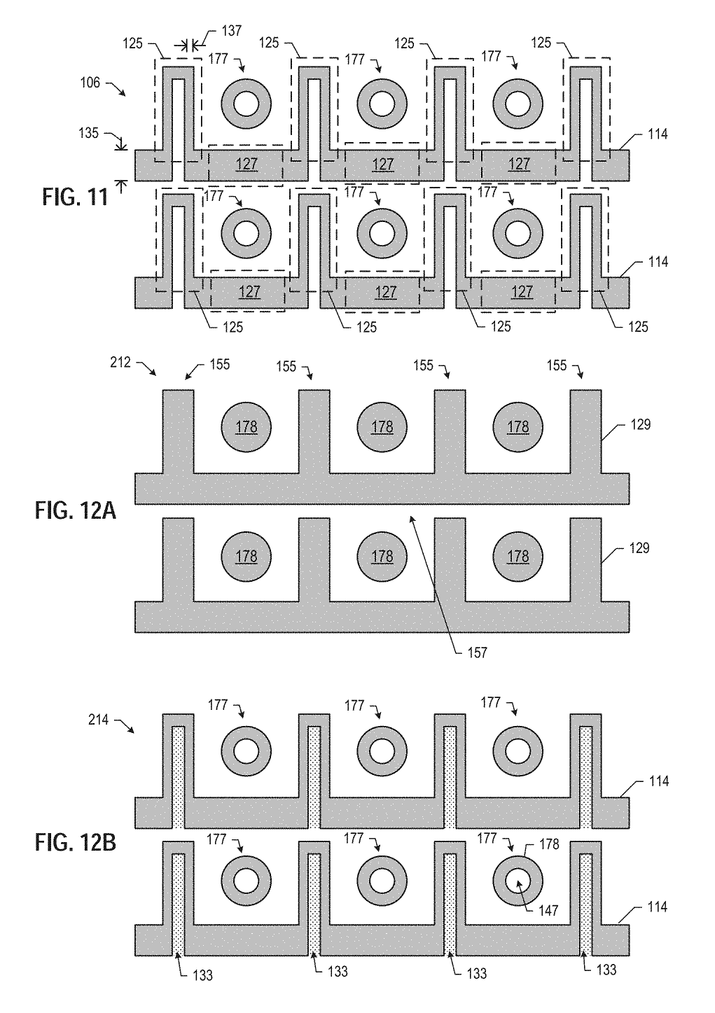

FIGS. 12A-12B illustrate various stages in the manufacture of the layer 108 of FIG. 11, in accordance with various embodiments. In particular, FIGS. 12A-12B illustrate a set of techniques that may be used to form the narrowed sections 125 of the heater traces 114 of FIG. 11.

FIG. 12A is a top view of the conductive material in an assembly 212, including conductive pads 178 arranged in a rectangular array, and initial traces 129. Each of the initial traces 129 illustrated in FIG. 12A may have a trunk section 157 and multiple branch sections 155 extending from the trunk section 157. These branch sections 155 may be “stubs” extending from the longer trunk section 157, in some embodiments. The trunk section 157 may be disposed between vias 177 in different rows, and the branch sections 155 may be disposed between vias 177 in different columns, as discussed above with reference to FIG. 11. The assembly 212 may be formed using conventional PCB manufacturing techniques, and thus may be subject to conventional PCB manufacturing design rules (e.g., the minimum trace width, minimum pad pitch, and minimum trace-to-pad clearance) and using conventional PCB manufacturing materials and processes (including any of those discussed above with reference to FIG. 8A).

FIG. 12B is a top view of the conductive material in an assembly 214, subsequent to removing at least some of the conductive material in the initial traces 129 of the assembly 212 (FIG. 12A) to form the heater traces 114, and drilling and plating openings 147 in the conductive pads 178 of the assembly 212 to form the conductive vias 177. In particular, FIG. 12B illustrates eight slots 133 (shown with dotted shading, with only four slots 133 labeled for economy of illustration) representing conductive material portions of the initial traces 129 of the assembly 212 that are removed to form the heater traces 114 of the assembly 214. Any suitable technique may be used to remove the conductive material of the initial traces 129 to form the heater traces 114, such as any of the techniques discussed above with reference to FIG. 8B, and the resulting slots 133 may have any of the dimensions or material properties discussed above with reference to FIG. 8B. Any conventional PCB techniques may be used for the drilling and plating operations. The resulting assembly 214 may take the form of the layer 108 illustrated in FIG. 11.

Note that, if the initial traces 129 of the assembly 212 of FIG. 12A were the heater traces 114 included in the IC package support structure 106, no current would flow into the branch sections 155, and thus no localized heating would occur between adjacent vias 177 in a particular row. By performing the post-processing operations discussed above with reference to FIG. 12B, the branch sections 155 may be formed into a dual-track arrangement through which current will flow, causing localized heating between adjacent vias 177 in a particular row.

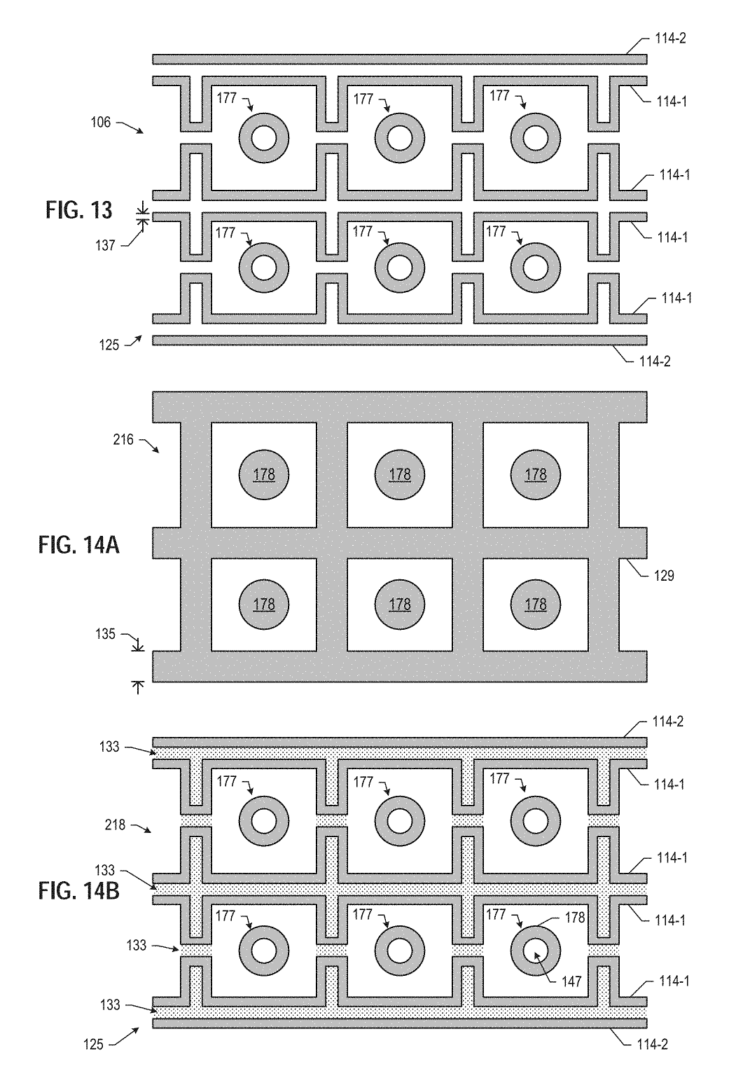

FIG. 13 is a top view of a layer 108 in an IC package support structure 106 including heater traces 114 narrower than a design rule minimum trace width, in accordance with various embodiments. The heater traces 114 illustrated in FIG. 13 may be part of larger heater traces 114 that may include wider sections (e.g., sections that have widths greater than or equal to the design rule minimum trace width), although such sections are not illustrated in FIG. 13; in other embodiments, the heater traces 114 may not have wider sections, and thus the entirety of the lengths of the heater traces 114 may have a width narrower than the design rule minimum trace width. More generally, the heater traces 114 illustrated in FIG. 13 may be sections of larger heater traces 114, and the remainders of those larger heater traces 114 may take any of the forms disclosed herein (e.g., may include any of the narrowed sections 125 or other features disclosed herein). Additionally, in some embodiments, the heater traces 114 of FIG. 13 may be conductively coupled in any desired combination outside of the view of the figure.

Four heater traces 114-1 and two heater traces 114-2 are depicted in FIG. 13, but a layer 108 may include any desired number of the heater traces 114. In FIG. 13, each of the heater traces 114-1 has a similar trunk-branch structure to that discussed above with reference to FIG. 11; however, in the embodiment of FIG. 13, the trunk and the branch sections of a heater trace 114-1 may both be narrower than the design rule minimum trace width. The heater traces 114-1 are arranged in mirror-image pairs around a row of intervening vias 177, as shown. Substantially linear heater traces 114-2 are shown above and below the array of vias 177. The vias 177 illustrated in FIG. 13 (and elsewhere herein) may take the form of plated through-holes, and may include conductive pads with a plated opening (not labeled in FIG. 13) extending between conductive pads on opposing faces of an insulating material (not shown).

The heater traces 114 of FIG. 13 may have a width 137; this width is only labeled on one of the heater traces 114 for economy of illustration. As noted above, in some embodiments, the width 137 of the heater traces 114 of FIG. 13 may be less than the design rule minimum trace width. Although the heater traces 114 of FIG. 13 are shown as having a substantially uniform width 137 along the contours of its shape (and a same width 137 among different ones of the heater traces 114), a heater trace 114 may have a width that varies along its length in any desired manner, and different heater traces 114 may have different widths.

FIGS. 14A-14B illustrate various stages in the manufacture of the layer 108 of FIG. 13, in accordance with various embodiments. In particular, FIGS. 14A-14B illustrate a set of techniques that may be used to form the heater traces 114 of FIG. 13.

FIG. 14A is a top view of the conductive material in an assembly 216, including conductive pads 178 arranged in a rectangular array, and an initial trace 129. The initial trace 129 may be patterned as a grid, with the conductive pads 178 arranged in the “openings” in the grid. The horizontal and vertical linear sections of the initial trace 129 may have a width 135 that is limited to be greater than or equal to a design rule minimum trace width. The assembly 216 may be formed using conventional PCB manufacturing techniques, and thus may be subject to conventional PCB manufacturing design rules (e.g., the minimum trace width, minimum pad pitch, and minimum trace-to-pad clearance) and using conventional PCB manufacturing materials and processes (including any of those discussed above with reference to FIG. 8A).

FIG. 14B is a top view of the conductive material in an assembly 218, subsequent to removing at least some of the conductive material in the initial trace 129 of the assembly 216 (FIG. 14A) to form the heater traces 114, and drilling and plating openings 147 in the conductive pads 178 of the assembly 216 to form the conductive vias 177. In particular, FIG. 14B illustrates eleven slots 133 (shown with dotted shading, with only four slots 133 labeled for economy of illustration) representing conductive material portions of the initial trace 129 of the assembly 216 that are removed to form the heater traces 114 of the assembly 218. Any suitable technique may be used to remove the conductive material of the initial trace 129 to form the heater traces 114, such as any of the techniques discussed above with reference to FIG. 8B, and the resulting slots 133 may have any of the dimensions or material properties discussed above with reference to FIG. 8B. Any conventional PCB techniques may be used for the drilling and plating operations. The resulting assembly 218 may take the form of the layer 108 illustrated in FIG. 13.

As discussed above with reference to FIG. 14B, multiple heater traces 114 of FIG. 13 may be formed by removing material from the wider initial trace 129 of FIG. 14A. In this manner, the techniques disclosed herein may be used to increase the number of heater traces 114 that can be included in a layer 108 relative to the number manufacturable using conventional PCB techniques. Including more heater traces 114 in a given layer 108 may allow the total number of layers 108 in an IC package support structure 106 to decrease relative to the number that would be necessary to pattern the same number of heater traces 114 using conventional PCB techniques, and thus advantageously reducing the material use, number of masks, and thickness of the IC package support structure 106 relative to its conventional counterpart.

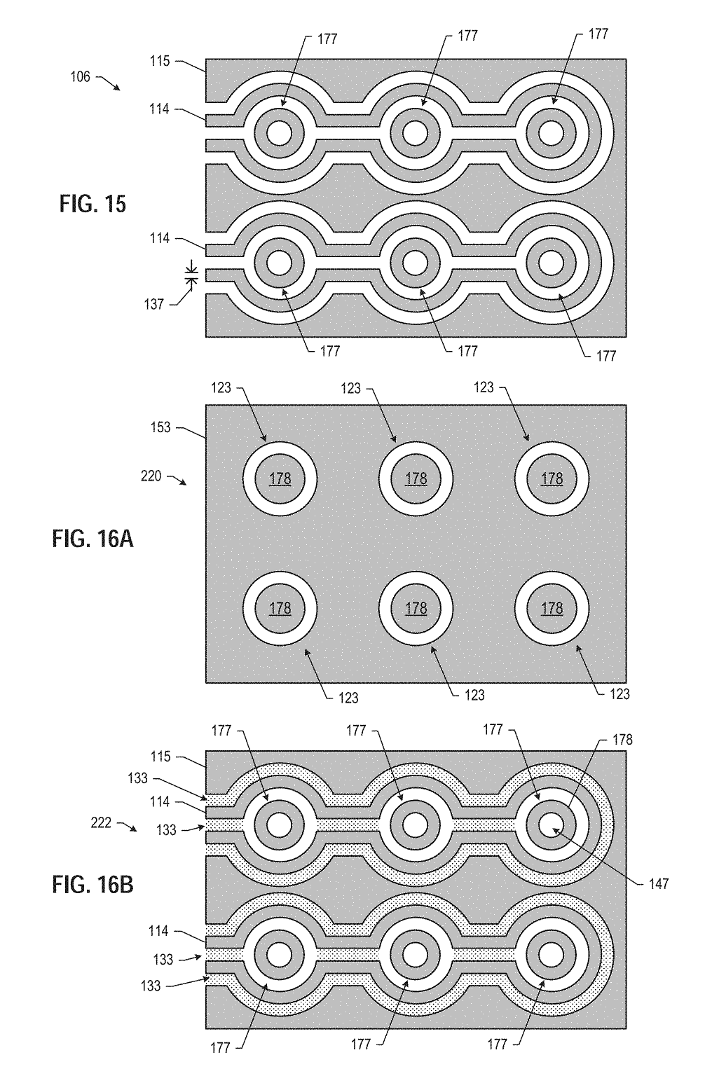

FIG. 15 is a top view of a layer 108 in an IC package support structure 106 including heater traces 114 and a metal plane 115, in accordance with various embodiments. In some embodiments, the heater traces 114 illustrated in FIG. 15 may have widths that are less than the design rule minimum trace width. The heater traces 114 illustrated in FIG. 15 may be part of larger heater traces 114 that may include wider sections (e.g., sections that have widths greater than or equal to the design rule minimum trace width), although such sections are not illustrated in FIG. 15; in other embodiments, the heater traces 114 may not have wider sections, and thus the entirety of the lengths of the heater traces 114 may have a width narrower than the design rule minimum trace width. More generally, the heater traces 114 illustrated in FIG. 15 may be sections of larger heater traces 114, and the remainders of those larger heater traces 114 may take any of the forms disclosed herein (e.g., may include any of the narrowed sections 125 or other features disclosed herein). Additionally, in some embodiments, the heater traces 114 of FIG. 15 may be conductively coupled in any desired combination outside of the view of the figure. The metal plane 115 illustrated in FIG. 15 may also be part of a larger metal plane 115 that may have any suitable size or shape.

Two heater traces 114 are depicted in FIG. 15, but a layer 108 may include any desired number of the heater traces 114. In FIG. 15, each of the heater traces 114 has a structure that includes straight segments coupled between curved segments that are spaced apart from and follow the contours of the vias 177; in particular, the heater traces 114 illustrated in FIG. 15 sandwich a row of vias 177, as shown. In the embodiment of FIG. 15, each heater trace 114 has an end curved segment that wraps around the “last” via 177 in a row (in FIG. 15, the rightmost vias 177 for the two heater traces 114). A metal plane 115 is shown extending around the heater traces 114 while being electrically separate from the heater traces 114; in FIG. 15, the metal plane 115 extends into the area between the two heater traces 114, as well as in the area around the two heater traces 114. The metal plane 115 may act as a heat spreader, helping mitigate warpage of the IC package support structure 106 during operation. The vias 177 illustrated in FIG. 15 (and elsewhere herein) may take the form of plated through-holes, and may include conductive pads with a plated opening (not labeled in FIG. 15) extending between conductive pads on opposing faces of an insulating material (not shown).

The heater traces 114 of FIG. 15 may have a width 137; this width is labeled on only one of the heater traces 114 for economy of illustration. As noted above, in some embodiments, the width 137 of the heater traces 114 of FIG. 15 may be less than the design rule minimum trace width. Although the heater traces 114 of FIG. 15 are shown as having a substantially uniform width 137 along the contours of its shape (and a same width 137 among different ones of the heater traces 114), a heater trace 114 may have a width that varies along its length in any desired manner, and different heater traces 114 may have different widths.

The metal plane 115 may be formed of any suitable material (e.g., copper) and may act as a heat spreader in the IC package support structure 106, as discussed above. The footprint of the metal plane 115 may have any desired shape.

FIGS. 16A-16B illustrate various stages in the manufacture of the layer 108 of FIG. 15, in accordance with various embodiments. In particular, FIGS. 16A-16B illustrate a set of techniques that may be used to form the heater traces 114 and the metal plane 115 of FIG. 15.

FIG. 16A is a top view of the conductive material in an assembly 220, including conductive pads 178 arranged in a rectangular array, and an initial metal plane 153. The initial metal plane 153 may be a flood of conductive material (e.g., copper) with holes 123 patterned into the flood. The conductive pads 178 may be disposed in the holes 123, and the holes 123 may serve to space the initial metal plane 153 (and the final metal plane 115) away from the vias 177. The assembly 220 may be formed using conventional PCB manufacturing techniques, and thus may be subject to conventional PCB manufacturing design rules (e.g., the minimum trace width, minimum pad pitch, and minimum trace-to-pad clearance) and using conventional PCB manufacturing materials and processes (including any of those discussed above with reference to FIG. 8A).

FIG. 16B is a top view of the conductive material in an assembly 222, subsequent to removing at least some of the conductive material in the initial metal plane 153 of the assembly 220 (FIG. 16A) to form the heater traces 114 and the metal plane 115, and drilling and plating openings 147 in the conductive pads 178 of the assembly 220 to form the conductive vias 177. In particular, FIG. 16B illustrates eight slots 133 (shown with dotted shading, with only four slots 133 labeled for economy of illustration) representing conductive material portions of the initial metal plane 153 of the assembly 220 that are removed to form the heater traces 114 and the metal plane 115 of the assembly 222. Any suitable technique may be used to remove the conductive material of the initial metal plane 153 to form the heater traces 114 and the metal plane 115, such as any of the techniques discussed above with reference to FIG. 8B, and the resulting slots 133 may have any of the dimensions or material properties discussed above with reference to FIG. 8B. Any conventional PCB techniques may be used for the drilling and plating operations. The resulting assembly 222 may take the form of the layer 108 illustrated in FIG. 15.

As discussed above with reference to FIG. 16B, the heater traces 114 may be formed by removing conductive material from the initial metal plane 153 of FIG. 16A, resulting in a metal plane 115 and heater traces 114 on a single layer 108 in the IC package support structure 106. Including heater traces 114 and metal planes 115 (e.g., for heat spreading purposes) in a single layer may reduce the overall layer count of the IC package support structure 106 relative to a more conventional support structure in which the metal plane 115 and the heater traces 114 are constrained to different layers 108.

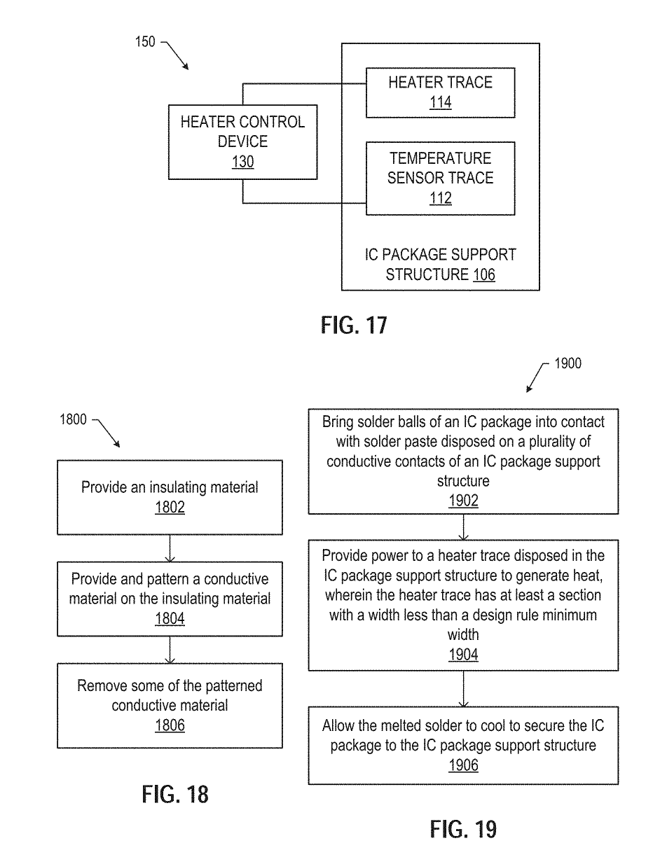

The heater traces 114 and/or the temperature sensor traces 112 of an IC package support structure 106 may be used in a reflow control system 150 to monitor and/or control the reflow of the solder 104. FIG. 17 is a block diagram of a reflow control system 150, in accordance with various embodiments. The system 150 may include one or more heater traces 114 of the IC package support structure 106, coupled to a heater control device 130 to control power provided to the heater trace 114. The heater control device 130 may be implemented using any controller device and technique known in the art (e.g., a programmed microcontroller). In some embodiments, an IC package support structure 106 may have a thermistor (e.g., a surface-mounted component, not shown) disposed at the second face 105; traces on the IC package support structure may couple to the thermistor, and these traces may be probed by the heater control device 130 to determine an initial temperature for the IC package support structure 106 for temperature sensor calibration.

In some embodiments, the system 150 may further include one or more temperature sensor traces 112, coupled to the heater control device 130. In such embodiments, the heater control device 130 may be configured to measure the resistance of the temperature sensor trace 112 and thereby determine the equivalent temperature of the temperature sensor trace 112, as discussed above. The heater control device 130 may then control the power provided to the heater traces 114 (e.g., by controlling the amount of DC or AC current injected into the heater traces 114) based on the equivalent temperature (e.g., increasing the power when the equivalent temperature is below a desired temperature, and vice versa). The heater traces 114 and the heater control device 130 may be configured to limit the heat generated by the heater traces 114 to avoid accidentally reflowing any solder other than that targeted for reflow, or otherwise exceeding any thermal constraints of the IC package assembly 120.

The IC package support structures 106 disclosed herein may be manufactured using any suitable method. For example, FIG. 18 is a flow diagram of a method 1800 of manufacturing an IC package support structure, in accordance with various embodiments. While the operations of the method 1800 are arranged in a particular order in FIG. 18 and illustrated once each, in various embodiments, one or more of the operations may be repeated or performed in parallel (e.g., when multiple IC package support structures are being manufactured). Operations discussed below with reference to the method 1800 may be illustrated with reference to the IC package support structure 106 of FIG. 1, but this is simply for ease of discussion, and the method 1800 may be used to manufacture any suitable IC package support structure.

At 1802, an insulating material may be provided. For example, the layer 108-9 of the IC package support structure 106 may be provided as part of a substrate (e.g., PCB) manufacturing procedure, as known in the art.

At 1804, a conductive material may be provided and patterned on the insulating material. For example, any of the initial traces 129 discussed above with reference to FIGS. 8, 10, 12, and 14 may be formed on the layer 108-9, or the initial metal plane 153 discussed above with reference to FIG. 16 may be formed on the layer 108-9. The operations discussed above with reference to 1802 and 1804 may be performed as part of a substrate-manufacturing procedure wherein different layers of the IC package support structure are formed in sequence.

At 1806, some of the patterned conductive material may be removed. For example, a laser cutting or other procedure may be used to remove conductive material from any of the initial traces 129 discussed above with reference to FIGS. 8, 10, 12, and 14 to form one or more narrowed sections 125 in a heater trace 114, and/or to remove conductive material from the initial metal plane 153 discussed above with reference to FIG. 16 to form a heater trace 114.

The IC package assemblies 120 disclosed herein may be manufactured using any suitable method. For example, FIG. 19 is a flow diagram of a method 1900 of attaching IC packages to an IC package support structure (e.g., during the manufacturing of an IC package assembly), in accordance with various embodiments. While the operations of the method 1900 are arranged in a particular order in FIG. 19 and illustrated once each, in various embodiments, one or more of the operations may be repeated or performed in parallel (e.g., when multiple IC package assemblies are being manufactured). Operations discussed below with reference to the method 1900 may be illustrated with reference to the assemblies 200 and 300 of FIGS. 4 and 5, respectively, but this is simply for ease of discussion, and the method 1900 may be used to manufacture any suitable IC package assembly.

At 1902, solder balls of an IC package may be brought into contact with solder paste disposed on a plurality of conductive contacts of an IC package support structure. For example, the solder balls 134 of the IC package 100-1 may be brought into contact with the solder paste 132 disposed on the conductive contacts 110-1 of the IC package support structure 106, as discussed above with reference to FIG. 4.

At 1904, power may be provided to a heater trace disposed in the IC package support structure to generate heat. The heater trace may have at least a section with a width less than a design rule minimum trace width, and the heat may be used to melt the solder balls and solder paste to form melted solder. For example, power may be provided to any of the heater traces 114 discussed above with reference to FIGS. 7, 9, 11, 13, and 15, included in the IC package support structure 106, to generate heat.

At 1906, the melted solder may be allowed to cool to secure the IC package to the IC package support structure. For example, the solder 104-1 may be formed by cooling the melted solder balls 134 and solder paste 132, as discussed above with reference to FIGS. 4 and 5.

FIG. 20 is a block diagram of an example computing device 500 that may include an IC package support structure 106 in accordance with the teachings of the present disclosure. In particular, any of the components of the computing device 500 that may be implemented at least partially in an IC package may be disposed on the IC package support structure 106. Alternatively or additionally, any of the components of the computing device 500 that may be secured to a substrate may be secured to the IC package support structure 106. A number of components are illustrated in FIG. 20 as included in the computing device 500, but any one or more of these components may be omitted or duplicated, as suitable for the application. In some embodiments, some or all of these components are fabricated onto a single system-on-a-chip (SoC) die (e.g., included in an IC package 100).

Additionally, in various embodiments, the computing device 500 may not include one or more of the components illustrated in FIG. 20, but the computing device 500 may include interface circuitry for coupling to the one or more components. For example, the computing device 500 may not include a display device 506, but may include display device interface circuitry (e.g., a connector and driver circuitry) to which a display device 506 may be coupled. In another set of examples, the computing device 500 may not include an audio input device 524 or an audio output device 508, but may include audio input or output device interface circuitry (e.g., connectors and supporting circuitry) to which an audio input device 524 or audio output device 508 may be coupled. Any one or more of the components of the computing device 500 may include one or more IC package support structures 106.

The computing device 500 may include a processing device 502 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 502 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. In some embodiments, the processing device 502 may be included in an IC package assembly 120 (e.g., in an IC package 100). The computing device 500 may include a memory 504, which may itself include one or more memory devices such as volatile memory (e.g., dynamic random access memory (DRAM)), non-volatile memory (e.g., read-only memory (ROM)), flash memory, solid state memory, and/or a hard drive. In some embodiments, the memory 504 may include memory that shares a die with the processing device 502. This memory may be used as cache memory and may include embedded DRAM (eDRAM) or spin transfer torque magnetic RAM (STT-MRAM). The memory 504 may be included in an IC package assembly 120 (e.g., secured to the IC package support structure 106).

In some embodiments, the computing device 500 may include a communication chip 512 (e.g., one or more communication chips). For example, the communication chip 512 may be configured for managing wireless communications for the transfer of data to and from the computing device 500. The term “wireless” and its derivatives may be used to describe circuits, devices, systems, methods, techniques, communication channels, etc., that may communicate data through the use of modulated electromagnetic radiation through a nonsolid medium. The term does not imply that the associated devices do not contain any wires, although in some embodiments they might not. The communication chip 512 may be included in the IC package assembly 120.

The communication chip 512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 512 may operate in accordance with other wireless protocols in other embodiments. The computing device 500 may include an antenna 522 to facilitate wireless communications and/or to receive other wireless communications (such as AM or FM radio transmissions).

In some embodiments, the communication chip 512 may manage wired communications, such as electrical, optical, or any other suitable communication protocols (e.g., the Ethernet). As noted above, the communication chip 512 may include multiple communication chips. For instance, a first communication chip 512 may be dedicated to shorter-range wireless communications such as Wi-Fi or Bluetooth, and a second communication chip 512 may be dedicated to longer-range wireless communications such as GPS, EDGE, GPRS, CDMA, WiMAX, LTE, EV-DO, or others. In some embodiments, a first communication chip 512 may be dedicated to wireless communications, and a second communication chip 512 may be dedicated to wired communications.

The computing device 500 may include battery/power circuitry 514. The battery/power circuitry 514 may include one or more energy storage devices (e.g., batteries or capacitors) and/or circuitry for coupling components of the computing device 500 to an energy source separate from the computing device 500 (e.g., AC line power). Some or all of the battery/power circuitry 514 may be secured to the IC package support structure 106, as noted above.

The computing device 500 may include a display device 506 (or corresponding interface circuitry, as discussed above). The display device 506 may include any visual indicators, such as a heads-up display, a computer monitor, a projector, a touchscreen display, a liquid crystal display (LCD), a light-emitting diode display, or a flat panel display, for example.

The computing device 500 may include an audio output device 508 (or corresponding interface circuitry, as discussed above). The audio output device 508 may include any device that generates an audible indicator, such as speakers, headsets, or earbuds, for example.

The computing device 500 may include an audio input device 524 (or corresponding interface circuitry, as discussed above). The audio input device 524 may include any device that generates a signal representative of a sound, such as microphones, microphone arrays, or digital instruments (e.g., instruments having a musical instrument digital interface (MIDI) output).

The computing device 500 may include a global positioning system (GPS) device 518 (or corresponding interface circuitry, as discussed above). The GPS device 518 may be in communication with a satellite-based system and may receive a location of the computing device 500, as known in the art. Some or all of the GPS device 518 may be secured to the IC package support structure 106, as noted above.

The computing device 500 may include an other output device 510 (or corresponding interface circuitry, as discussed above). Examples of the other output device 510 may include an audio codec, a video codec, a printer, a wired or wireless transmitter for providing information to other devices, or an additional storage device.

The computing device 500 may include an other input device 520 (or corresponding interface circuitry, as discussed above). Examples of the other input device 520 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 500 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 500 may be any other electronic device that processes data.

The following paragraphs provide various examples of the embodiments disclosed herein.

Example 1 is a device, including: a printed circuit board (PCB) including an insulating material, and a heater trace on the insulating material, wherein the heater trace has a section with a width less than 3.5 mils.

Example 2 may include the subject matter of Example 1, and may further specify that the section of the heater trace is a first section, and the heater trace includes a second section with a width greater than 3.5 mils.

Example 3 may include the subject matter of Example 2, and may further specify that the heater trace includes a third section with a width greater than 3.5 mils, and the first section is between the second section and the third section.

Example 4 may include the subject matter of any of Examples 1-3, and may further specify that the section has a width less than 1.75 mils.

Example 5 may include the subject matter of any of Examples 1-4, and may further specify that the section has a width less than 1.25 mils.

Example 6 may include the subject matter of any of Examples 1-5, and may further specify that the section of the heater trace has a serpentine shape.

Example 7 may include the subject matter of any of Examples 1-6, and may further specify that the section of the heater trace is adjacent to a laser-burned portion of the insulating material.

Example 8 may include the subject matter of any of Examples 1-7, and may further specify that the heater trace has multiple sections with widths less than 3.5 mils.

Example 9 may include the subject matter of Example 8, and may further specify that the multiple sections are multiple branches with trunk sections therebetween, and the trunk sections have widths greater than or equal to 3.5 mils.

Example 10 may include the subject matter of any of Examples 8-9, and may further specify that the multiple sections are multiple branches with trunk sections therebetween, the heater trace is a first heater trace, and the PCB further includes a second heater trace arranged as a mirror image of the first heater trace.

Example 11 may include the subject matter of any of Examples 8-10, and may further specify that the PCB further includes a metal plane in a same layer of the PCB as the heater trace, and the PCB does not include conductive contacts to the metal plane.

Example 12 may include the subject matter of any of Examples 1-11, and may further specify that the PCB includes a first via to a power or ground plane and a second via to a signal line, and the section is closer to the first via than to the second via.

Example 13 may include the subject matter of any of Examples 1-12, and may further specify that the section of the heater trace is adjacent to a burned portion of the insulating material.

Example 14 may include the subject matter of any of Examples 1-13, and may further specify that the PCB includes a plurality of vias having a pitch greater than or equal to 0.8 millimeters.

Example 15 may include the subject matter of any of Examples 1-14, and may further specify that the device includes an interposer, and the interposer includes the PCB.

Example 16 may include the subject matter of any of Examples 1-14, and may further specify that the device includes a motherboard, and the motherboard includes the PCB.

Example 17 may include the subject matter of any of Examples 1-16, and may further specify that the PCB further includes: conductive contacts; and a ball grid array (BGA) package coupled to the conductive contacts via solder.

Example 18 may include the subject matter of Example 17, and may further specify that the BGA package includes a processing device.

Example 19 may include the subject matter of any of Examples 17-18, and may further specify that the BGA package includes a memory device.

Example 20 may include the subject matter of any of Examples 17-19, and may further include a heater control device in conductive contact with the heater trace, wherein the heater control device is to deliver power to the heater trace to generate heat to melt solder disposed on the conductive contacts.

Example 21 may include the subject matter of any of Examples 17, and may further include a display device.

Example 22 may include the subject matter of any of Examples 17, and may further include one or more communication chips.

Example 23 is a device, including: a printed circuit board (PCB) including an insulating material, and a heater trace on the insulating material, wherein a section of the heater trace is adjacent to a burned portion of the insulating material.

Example 24 may include the subject matter of Example 23, and may further specify that the heater trace at least partially wraps around the burned portion of the insulating material.

Example 25 may include the subject matter of any of Examples 23-35, and may further specify that the burned portion of the insulating material includes an L-shaped portion of the insulating material.

Example 26 may include the subject matter of any of Examples 23-25, and may further specify that the heater trace is a first heater trace, the PCB includes a second heater trace, and the second heater trace is adjacent to the burned portion of the insulating material.

Example 27 may include the subject matter of Example 26, and may further specify that the second heater trace is a mirror image of the first heater trace on the insulating material.

Example 28 may include the subject matter of any of Examples 23-27, and may further specify that the insulating material includes a glass epoxy.

Example 29 may include the subject matter of any of Examples 23-28, and may further specify that the heater trace includes a copper foil.

Example 30 may include the subject matter of any of Examples 23-29, and may further specify that the device includes an interposer, and the interposer includes the PCB.

Example 31 may include the subject matter of any of Examples 23-29, and may further specify that the PCB is a motherboard.

Example 32 may include the subject matter of any of Examples 23-31, and may further include: conductive contacts; and a ball grid array (BGA) package coupled to the conductive contacts via solder.

Example 33 may include the subject matter of Example 32, and may further specify that the BGA package includes a processing device.

Example 34 may include the subject matter of any of Examples 32-33, and may further specify that the BGA package includes a memory device.

Example 35 may include the subject matter of any of Examples 32-34, and may further include a heater control device in conductive contact with the heater trace, wherein the heater control device is to deliver power to the heater trace to generate heat to melt solder disposed on the conductive contacts.

Example 36 may include the subject matter of any of Examples 32-35, and may further include a display device.

Example 37 may include the subject matter of any of Examples 32-36, and may further include one or more communication chips.

Example 38 is a method of manufacturing a printed circuit board (PCB), including: providing an insulating material; forming a trace with a conductive material on the insulating material; and removing at least a portion of the conductive material to form a narrowed section of the trace.

Example 39 may include the subject matter of any of Examples 38, and may further specify that removing at least a portion of the conductive material includes laser cutting the trace.

Example 40 may include the subject matter of Example 38, and may further specify that removing at least a portion of the conductive material includes forming one or more slots in the trace.

Example 41 may include the subject matter of Example 40, and may further specify that the one or more slots includes a slot with an L-shaped portion.

Example 42 may include the subject matter of any of Examples 38-41, and may further specify that the trace has a width, when formed, greater than or equal to 3.5 mils.

Example 43 may include the subject matter of any of Examples 38-42, and may further specify that the narrowed section of the trace has a serpentine shape.

Example 44 may include the subject matter of any of Examples 38-43, and may further specify that the insulating material includes a glass epoxy.

Example 45 may include the subject matter of any of Examples 38-44, and may further specify that forming the trace includes patterning a copper foil.

Example 46 may include the subject matter of any of Examples 38-45, and may further specify that the trace is a heater trace.

Example 47 is a method of manufacturing a printed circuit board (PCB), including: providing an insulating material; providing a plane of conductive material on the insulating material; and removing some of the conductive material to form a trace in the conductive material.

Example 48 may include the subject matter of Example 47, and may further specify that the conductive material plane is a copper plane.

Example 49 may include the subject matter of any of Examples 47-48, and may further specify that removing some of the conductive material includes laser cutting the conductive material.

Example 50 may include the subject matter of any of Examples 47-49, and may further specify that the insulating material includes a glass epoxy.

Example 51 may include the subject matter of any of Examples 47-50, and may further specify that the trace extends around multiple via pads.

Example 52 is a method of manufacturing an integrated circuit (IC) package assembly, including: bringing solder balls of an IC package into contact with solder paste disposed on a plurality of conductive contacts of an IC package support structure; providing power to a heater trace disposed in the IC package support structure to generate heat to melt the solder balls and the solder paste to form melted solder, wherein the heater trace has at least a section with a width less than a design rule minimum trace width; and allowing the melted solder to cool to secure the IC package to the IC package support structure.

Example 53 may include the subject matter of Example 52, and may further specify that the IC package support structure has a layer including a metal plane and a trace, and wherein a burned portion of insulating material is between the metal plane and the trace in the layer.

Example 54 may include the subject matter of any of Examples 52-53, and may further specify that the IC package includes a processing device.

Example 55 may include the subject matter of any of Examples 52-54, and may further specify that the power is provided to the heater trace by a heater control device brought into temporary conductive contact with the heater trace.

Example 56 may include the subject matter of any of Examples 52-55, and may further include, after allowing the melted solder to cool to secure the IC package to the IC package support structure, providing power to the heater trace to generate heat to melt the cooled solder.

Example 57 may include the subject matter of Example 56, and may further include, after providing the power to the heater trace to generate heat to melt the cooled solder, removing the IC package from contact with the IC package support structure.

Example 58 may include a device manufactured in accordance with any of the methods of Examples 38-57.

Example 59 may include the subject matter of any of Examples 1-58, and may further specify that the slot has a trapezoidal cross-section.

Example 60 may include the subject matter of Example 59, and may further specify that the cross-section of the slot tapers toward the insulating material.

1. A device, comprising:
a printed circuit board (PCB) including:
an insulating material, and
a metal trace on the insulating material, wherein a section of the metal trace is adjacent to a burned portion of the insulating material.

2. The device of claim 1, wherein the metal trace at least partially wraps around the burned portion of the insulating material.

3. The device of claim 1, wherein the metal trace is a first metal trace, the PCB includes a second metal trace, and the second metal trace is adjacent to the burned portion of the insulating material.

4. The device of claim 3, wherein the second metal trace is a mirror image of the first metal trace on the insulating material.

5. The device of claim 1, wherein the device includes an interposer, and the interposer includes the PCB.

6. The device of claim 1, wherein:
the PCB includes conductive contacts; and
the device further includes a ball grid array (BGA) package coupled to the conductive contacts via solder.

7. The device of claim 6, further comprising:
a heater control device in conductive contact with the metal trace, wherein the heater control device is to deliver power to the metal trace to generate heat to melt the solder on the conductive contacts.

8. A device, comprising:
a printed circuit board (PCB) including:
an insulating material, and
a heater trace on the insulating material, wherein the heater trace has a section with a width less than 3.5 mils.

9. The device of claim 8, wherein the section of the heater trace is a first section, and the heater trace includes a second section with a width greater than 3.5 mils.

10. The device of claim 8, wherein the width of the section is less than 1.25 mils.

11. The device of claim 8, wherein the section of the heater trace has a serpentine shape.

12. The device of claim 8, wherein the section is a first section of the heater trace, and the heater trace includes at least one additional section having a width that is less than 3.5 mils.

13. The device of claim 12, wherein the sections are multiple branches with trunk sections therebetween, and the trunk sections have widths greater than or equal to 3.5 mils.

14. The device of claim 12, wherein the sections are multiple branches with trunk sections therebetween, the heater trace is a first heater trace, and the PCB further includes a second heater trace arranged as a mirror image of the first heater trace.

15. The device of claim 12, wherein the PCB further includes a metal plane in a same layer of the PCB as the heater trace, and the PCB does not include conductive contacts to the metal plane.

16. The device of claim 8, wherein the PCB includes a first via to a power or ground plane and a second via to a signal line, and the section is closer to the first via than to the second via.

17. The device of claim 8, wherein the section of the heater trace is adjacent to a burned portion of the insulating material.

18-25. (canceled)

26. The device of claim 1, wherein the metal trace is a heater trace.

27. A device, comprising:
a printed circuit board (PCB) including:
an insulating material, and
a trace on the insulating material, wherein a section of the trace is adjacent to a burned portion of the insulating material, and the section of the trace includes a material different from the burned portion of the insulating material.

28. The device of claim 27, wherein the trace includes a metal.

29. The device of claim 27, wherein the insulating material includes a glass epoxy.

30. The device of claim 27, wherein the trace is a heater trace such that, when a heater control device is in conductive contact with the heater trace, the heater control device is to deliver power to the heater trace to generate heat to melt solder on conductive contacts of the PCB.

31. A device, comprising:
a printed circuit board (PCB) including:
an insulating material including a glass epoxy, and
a trace on the insulating material, wherein a section of the trace is adjacent to a burned portion of the insulating material.

32. The device of claim 31, wherein the section has a width less than 3.5 mils.

33. The device of claim 31, wherein the trace is a heater trace.
